(19) United States
(12) Patent Application Publication
(10) Pub. No.: US 2019/0381763 A1
(43) Pub. Date: Dec. 19, 2019

(54) GRAPHITE COMPOSITE FILM AND METHOD FOR PRODUCING SAME

(71) Applicant: Panasonic Intellectual Property Management Co., Ltd., Osaka (JP)

(72) Inventors: YASUHIRO TSUDA, Osaka (JP); JUNICHIRO HIRATSUKA, Shimane (JP); CHIHIRO SATOU, Hokkaido (JP)

(21) Appl. No.: 16/558,193

(22) Filed: Sep. 2, 2019

Related U.S. Application Data
(63) Continuation of application No. PCT/JP2018/010679, filed on Mar. 19, 2018.

(30) Foreign Application Priority Data
Apr. 7, 2017 (JP) 2017-077044
Apr. 7, 2017 (JP) 2017-077045

(51) Int. Cl. B32B 9/00; H05K 7/20; H05K 9/00; B32B 7/12; B32B 9/04; B32B 15/20; B32B 15/04; B32B 27/36; B32B 15/09; B32B 37/12; B32B 37/02; B32B 37/18; C23C 14/00; C23C 14/20; C23C 14/24; C23C 14/16; C25D 3/12; F28F 21/02; F28F 21/08

(52) U.S. Cl. CPC B32B 9/007; B32B 2307/212; H05K 9/0088; B32B 7/12; B32B 9/041; B32B 15/20; B32B 15/043; B32B 27/36; B32B 15/09; B32B 37/12; B32B 37/02; B32B 37/18; C23C 14/0005; C23C 14/20; C23C 14/24; C23C 14/16; C25D 3/12; F28F 21/02; F28F 21/089; B32B 2255/06; B32B 2255/205; B32B 2307/202; B32B 2311/12; B32B 2311/22; B32B 2313/04; B32B 2367/00; B32B 2405/00; H05K 7/2039

(57) ABSTRACT

Provided is a graphite composite film that is capable of attaining both a measure against heat and a measure against electromagnetic noise and that has excellent high-frequency electromagnetic wave shielding performance. The graphite composite film is configured to include a graphite layer, a first electrically conductive adhesive layer, a first metal layer containing a first metal, and a second metal layer containing a second metal disposed in this order. With an arithmetic average roughness of a surface on a first electrically conductive adhesive layer-disposed side of the first metal layer defined as Ra₁ and an arithmetic average roughness of a surface of the second metal layer opposite from a surface on a first metal layer-disposed side of the second metal layer defined as Ra₂, at least one of the Ra₁ or the Ra₂ is less than or equal to 50 nm.

### BACKGROUND

### 1. Technical Field

The present disclosure relates to a graphite composite film and a method for producing the graphite composite film.

### 2. Description of the Related Art

In recent years, high performance and reduction in size and thickness are required of electronic devices such as a communication device and a personal computer to increase a circuit operation frequency, and along with the requirements, many electronic components are disposed without a gap in a limited space within a housing of an electronic device. These electronic components become sources of heat and electromagnetic noise to possibly cause a malfunction of an electronic device or reception difficulty of, for example, a television. Further, along with high adoption of, for example, wireless local network (LAN), high-frequency electromagnetic waves are travelling around an electronic device and such electromagnetic waves enter into the electronic device to possibly cause a malfunction of the electronic device. Therefore, a measure against heat and a measure against electromagnetic noise are important issues.

As such a measure against heat and a measure against electromagnetic noise, PTL (Patent Literature) 1 discloses a graphite sheet composite sheet obtained by stacking an adhesion layer formed of a prescribed electrically conductive adhesive agent composition, a 35-μm rolled copper foil, an adhesion layer formed of the electrically conductive adhesive agent composition, and a graphite sheet in this order.

### CITATION LIST

### Patent Literature

PTL 1: Unexamined Japanese Patent Publication No. 2014-56967

### SUMMARY

The graphite sheet composite sheet described in PTL 1, however, does not possibly have electromagnetic wave shielding performance enough for shielding a high-frequency electromagnetic wave of more than or equal to 5 GHz.

Thus, an object of the present disclosure is to provide a graphite composite film that is capable of attaining both a measure against heat and a measure against electromagnetic noise and that has excellent high-frequency electromagnetic wave shielding performance and to provide a method for producing the graphite composite film.

A graphite composite film according to a first aspect of the present disclosure has a structure including a graphite layer, a first electrically conductive adhesive layer, a first metal layer containing a first metal, and a second metal layer containing a second metal disposed in this order. Ra₁ is defined as an arithmetic average roughness of a surface of the first metal layer, the surface being a surface on which the first electrically conductive adhesive layer is disposed, and Ra₂ is defined as an arithmetic average roughness of a first surface of the second metal layer, the first surface opposing a second surface of the second metal layer, the second surface being a surface on which the first metal layer is disposed, at least one of Ra₁ or Ra₂ is less than or equal to 50 nm.

A method for producing a graphite composite film according to a second aspect of the present disclosure includes following steps. That is, vapor deposition of a first metal is performed on a first surface of a protection film having the first surface and a second surface, to form a first metal layer. Thereafter, a first electrically conductive adhesive sheet is disposed on a surface of the first metal layer, thus laminating the surface with the first electrically conductive adhesive sheet. Thereafter, the protection film is peeled. Then, vapor deposition of a second metal is performed on a surface of the first metal opposite from the surface on a first electrically conductive adhesive sheet-disposed side of the first metal layer to form a second metal layer. Thus, an electrically conductive adhesive sheet-attached metal vapor-deposited film is prepared. The method for producing a graphite composite film includes this step of preparing an electrically conductive adhesive sheet-attached metal vapor-deposited film. Further, a second electrically conductive adhesive sheet is disposed on a first surface of a graphite film having the first surface and a second surface, thus laminating the graphite film with the second electrically conductive adhesive sheet, to prepare an electrically conductive adhesive sheet-attached graphite film. The method for producing a graphite composite film includes this step of preparing an electrically conductive adhesive sheet-attached graphite film. Then, the electrically conductive adhesive sheet-attached metal vapor-deposited film and the electrically conductive adhesive sheet-attached graphite film are disposed such that a surface of the first electrically conductive adhesive sheet and the second surface of the graphite film are disposed so as to overlap one another, thus laminating the electrically conductive adhesive sheet-attached metal vapor-deposited film with the electrically conductive adhesive sheet-attached graphite film. The method for producing a graphite composite film includes this step of laminating the electrically conductive adhesive sheet-attached metal vapor-deposited film. An arithmetic average roughness of the surface on the first electrically conductive adhesive sheet-disposed side of the first metal layer is defined as Ra₁. An arithmetic average roughness of the surface of the second metal layer opposite from the surface on the first meta layer-disposed side of the second metal layer is defined as Ra₂. At this time, at least one of the Ra₁ or the Ra₂ is less than or equal to 50 nm.

A method for producing a graphite composite film according to a third aspect of the present disclosure includes following steps. That is, vapor deposition of a second metal and a first metal is performed in this order on a first surface of a protection film having the first surface and a second surface. Thus, a second metal layer containing the second metal and a first metal layer containing the first metal are formed. Thereafter, a first electrically conductive adhesive sheet is disposed on a surface of the first metal layer, thus laminating the surface with the first electrically conductive adhesive sheet. Thereafter, the protection film is peeled. Thus, an electrically conductive adhesive sheet-attached metal vapor-deposited film is prepared. The method for producing a graphite composite film includes this step of preparing an electrically conductive adhesive sheet-attached metal vapor-deposited film. A second electrically conductive adhesive sheet is disposed on a first surface of a graphite film having the first surface and a second surface, thus laminating the first surface with the second electrically conductive adhesive sheet, to prepare an electrically conductive adhesive sheet-attached graphite film. The method for producing a graphite composite film includes this step of preparing an electrically conductive adhesive sheet-attached graphite film. Then, the electrically conductive adhesive sheet-attached metal vapor-deposited film and the electrically conductive adhesive sheet-attached graphite film are subjected to lamination, with a surface of the first electrically conductive adhesive sheet and the second surface of the graphite film disposed so as to overlap one another. The method for producing a graphite composite film includes this laminating step. At this time, with an arithmetic average roughness of a surface on a first electrically conductive adhesive sheet-disposed side of the first metal layer defined as Ra₁ and an arithmetic average roughness of a surface of the second metal layer opposite from a surface on a first metal layer-disposed side of the second metal layer defined as Ra₂, at least one of the Ra₁ or the Ra₂ is less than or equal to 50 nm.

A graphite composite film according to a fourth aspect of the present disclosure has a structure including a graphite layer, a first electrically conductive adhesive layer, a metal layer that contains a metal and has a first surface and a second surface, and a protection film in this order, with the protection film disposed to position on a side of the first surface of the metal layer. At least one of the first surface or the second surface of the metal layer has an arithmetic average roughness (Ra) of less than or equal to 50 nm.

A method for producing a graphite composite film according to a fifth aspect of the present disclosure includes following steps. Vapor deposition of a metal is performed on a first surface of a protection film having the first surface and a second surface, to form a metal layer having a first surface and a second surface. Then, a first electrically conductive adhesive sheet is disposed on the second surface of the metal layer, thus laminating the metal layer with the first electrically conductive adhesive sheet, to prepare an electrically conductive adhesive sheet-attached metal vapor-deposited film. The method for producing a graphite composite film includes this step of preparing an electrically conductive adhesive sheet-attached metal vapor-deposited film. A second electrically conductive adhesive sheet is disposed on a first surface of a graphite film having the first surface and a second surface, thus laminating the graphite film with the second electrically conductive adhesive sheet, to prepare an electrically conductive adhesive sheet-attached graphite film. The method for producing a graphite composite film includes this step of preparing an electrically conductive adhesive sheet-attached graphite film. Then, the electrically conductive adhesive sheet-attached metal vapor-deposited film and the electrically conductive adhesive sheet-attached graphite film are subjected to lamination, with a surface of the first electrically conductive adhesive sheet and the second surface of the graphite film disposed so as to overlap one another. The method for producing a graphite composite film includes this laminating step. At this time, at least one of the first surface or the second surface of the metal layer has an arithmetic average roughness (Ra) of less than or equal to 50 nm.

A technique according to the present disclosure is capable of attaining both a measure against heat and a measure against electromagnetic noise and has excellent high-frequency electromagnetic wave shielding performance.

### BRIEF DESCRIPTION OF THE DRAWINGS

FIG. 1A is a schematic sectional view of a main portion of a graphite composite film according to a first exemplary embodiment of the present disclosure;

FIG. 1B is a schematic sectional view of an end portion of the graphite composite film according to the first exemplary embodiment of the present disclosure;

FIG. 2A is a schematic sectional view for illustrating part of a first method for producing the graphite composite film according to the first exemplary embodiment of the present disclosure, specifically a schematic sectional view for illustrating one example of a step of preparing an electrically conductive adhesive sheet-attached metal vapor-deposited film;

FIG. 2B is a schematic sectional view for illustrating the part of the first method for producing the graphite composite film according to the first exemplary embodiment of the present disclosure, specifically a schematic sectional view for illustrating the one example of the step of preparing an electrically conductive adhesive sheet-attached metal vapor-deposited film;

FIG. 2C is a schematic sectional view for illustrating the part of the first method for producing the graphite composite film according to the first exemplary embodiment of the present disclosure, specifically a schematic sectional view for illustrating the one example of the step of preparing an electrically conductive adhesive sheet-attached metal vapor-deposited film;

FIG. 2D is a schematic sectional view for illustrating the part of the first method for producing the graphite composite film according to the first exemplary embodiment of the present disclosure, specifically a schematic sectional view for illustrating the one example of the step of preparing an electrically conductive adhesive sheet-attached metal vapor-deposited film;

FIG. 2E is a schematic sectional view for illustrating the part of the first method for producing the graphite composite film according to the first exemplary embodiment of the present disclosure, specifically a schematic sectional view for illustrating the one example of the step of preparing an electrically conductive adhesive sheet-attached metal vapor-deposited film;

FIG. 2F is a schematic sectional view for illustrating the part of the first method for producing the graphite composite film according to the first exemplary embodiment of the present disclosure, specifically a schematic sectional view for illustrating the one example of the step of preparing an electrically conductive adhesive sheet-attached metal vapor-deposited film;

FIG. 3A is a schematic sectional view for illustrating part of a second method for producing the graphite composite film according to the first exemplary embodiment of the present disclosure, specifically a schematic sectional view for illustrating one example of the step of preparing an electrically conductive adhesive sheet-attached metal vapor-deposited film;

FIG. 3B is a schematic sectional view for illustrating the part of the second method for producing the graphite composite film according to the first exemplary embodiment of the present disclosure, specifically a schematic sectional view for illustrating the one example of the step of preparing an electrically conductive adhesive sheet-attached metal vapor-deposited film;

FIG. 3C is a schematic sectional view for illustrating the part of the second method for producing the graphite composite film according to the first exemplary embodiment of the present disclosure, specifically a schematic sectional view for illustrating the one example of the step of preparing an electrically conductive adhesive sheet-attached metal vapor-deposited film;

FIG. 3D is a schematic sectional view for illustrating the part of the second method for producing the graphite composite film according to the first exemplary embodiment of the present disclosure, specifically a schematic sectional view for illustrating the one example of the step of preparing an electrically conductive adhesive sheet-attached metal vapor-deposited film;

FIG. 3E is a schematic sectional view for illustrating the part of the second method for producing the graphite composite film according to the first exemplary embodiment of the present disclosure, specifically a schematic sectional view for illustrating the one example of the step of preparing an electrically conductive adhesive sheet-attached metal vapor-deposited film;

FIG. 3F is a schematic sectional view for illustrating the part of the second method for producing the graphite composite film according to the first exemplary embodiment of the present disclosure, specifically a schematic sectional view for illustrating the one example of the step of preparing an electrically conductive adhesive sheet-attached metal vapor-deposited film;

FIG. 4A is a schematic sectional view for illustrating part of the first and second methods for producing the graphite composite film according to the first exemplary embodiment of the present disclosure, specifically a schematic sectional view for illustrating a step of preparing an electrically conductive adhesive sheet-attached graphite film;

FIG. 4B is a schematic sectional view for illustrating the part of the first and second methods for producing the graphite composite film according to the first exemplary embodiment of the present disclosure, specifically a schematic sectional view for illustrating the step of preparing an electrically conductive adhesive sheet-attached graphite film;

FIG. 4C is a schematic sectional view for illustrating part of the first and second methods for producing the graphite composite film according to the first exemplary embodiment of the present disclosure, specifically a schematic sectional view for illustrating a step of subjecting the electrically conductive adhesive sheet-attached metal vapor-deposited film and the electrically conductive adhesive sheet-attached graphite film to lamination;

FIG. 4D is a schematic sectional view for illustrating the part of the first and second methods for producing the graphite composite film according to the first exemplary embodiment of the present disclosure, specifically a schematic sectional view for illustrating the step of subjecting the electrically conductive adhesive sheet-attached metal vapor-deposited film and the electrically conductive adhesive sheet-attached graphite film to lamination;

FIG. 5A is a schematic sectional view of a main portion of a graphite composite film according to a second exemplary embodiment of the present disclosure;

FIG. 5B is a schematic sectional view of an end portion of the graphite composite film according to the second exemplary embodiment of the present disclosure;

FIG. 6A is a schematic sectional view for illustrating a method for producing the graphite composite film according to the second exemplary embodiment of the present disclosure, specifically a schematic sectional view for illustrating a step of preparing an electrically conductive adhesive sheet-attached metal vapor-deposited film;

FIG. 6B is a schematic sectional view for illustrating the method for producing the graphite composite film according to the second exemplary embodiment of the present disclosure, specifically a schematic sectional view for illustrating the step of preparing an electrically conductive adhesive sheet-attached metal vapor-deposited film;

FIG. 6C is a schematic sectional view for illustrating the method for producing the graphite composite film according to the second exemplary embodiment of the present disclosure, specifically a schematic sectional view for illustrating the step of preparing an electrically conductive adhesive sheet-attached metal vapor-deposited film;

FIG. 6D is a schematic sectional view for illustrating the method for producing the graphite composite film according to the second exemplary embodiment of the present disclosure, specifically a schematic sectional view for illustrating the step of preparing an electrically conductive adhesive sheet-attached metal vapor-deposited film;

FIG. 6E is a schematic sectional view for illustrating the method for producing the graphite composite film according to the second exemplary embodiment of the present disclosure, specifically a schematic sectional view for illustrating a step of preparing an electrically conductive adhesive sheet-attached graphite film;

FIG. 6F is a schematic sectional view for illustrating the method for producing the graphite composite film according to the second exemplary embodiment of the present disclosure, specifically a schematic sectional view for illustrating the step of preparing an electrically conductive adhesive sheet-attached graphite film;

FIG. 6G is a schematic sectional view for illustrating the method for producing the graphite composite film according to the second exemplary embodiment of the present disclosure, specifically a schematic sectional view for illustrating a step of subjecting the electrically conductive adhesive sheet-attached metal vapor-deposited film and the electrically conductive adhesive sheet-attached graphite film to lamination; and

FIG. 6H is a schematic sectional view for illustrating the method for producing the graphite composite film according to the second exemplary embodiment of the present disclosure, specifically a schematic sectional view for illustrating the step of subjecting the electrically conductive adhesive sheet-attached metal vapor-deposited film and the electrically conductive adhesive sheet-attached graphite film to lamination.

### DETAILED DESCRIPTION

Exemplary embodiments of the present disclosure are described below.

### First Exemplary Embodiment

### [Graphite Composite Film 1 According to Present Exemplary Embodiment]

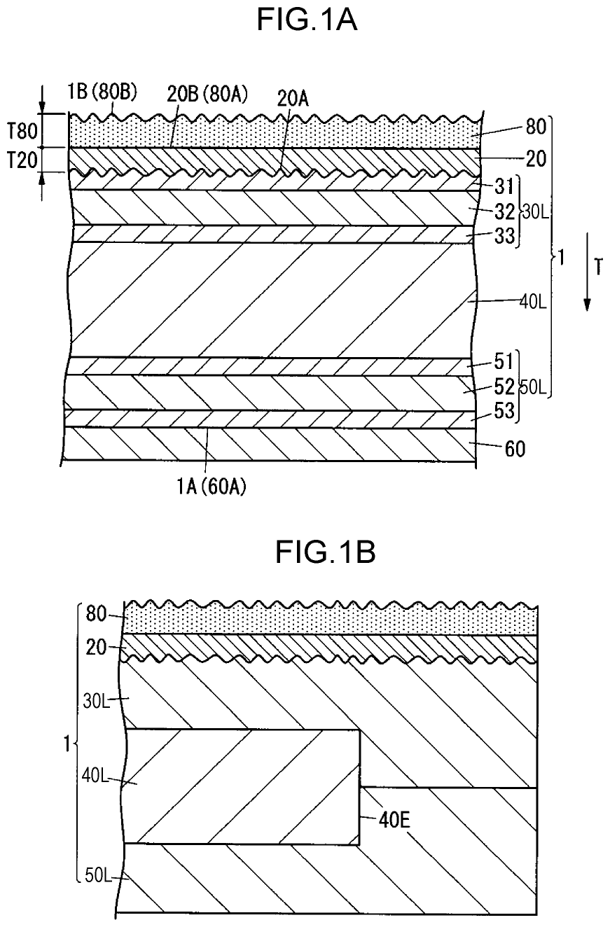

FIG. 1A is a schematic sectional view of a main portion of graphite composite film 1 according to a first exemplary embodiment. FIG. 1B is a schematic sectional view of an end portion of graphite composite film 1.

Graphite composite film 1 according to the present exemplary embodiment has a structure including, as shown in FIG. 1A, second electrically conductive adhesive layer 50L, graphite layer 40L, first electrically conductive adhesive layer 30L, first metal layer 20 containing a first metal, and second metal layer 80 containing a second metal stacked in this order. With an arithmetic average roughness of surface 20A on a first electrically conductive adhesive layer 30L-disposed side of first metal layer 20 defined as Ra₁ and an arithmetic average roughness of surface 80B of second metal layer 80 opposite from surface 80A on a first metal layer 20-disposed side of second metal layer 80 defined as Ra₂, at least one of the Ra₁ or the Ra₂ is less than or equal to 50 nm. Further, first peeling sheet 60 is fitted to surface 1A of second electrically conductive adhesive layer 50L. Here, the arithmetic average roughness (Ra₁ and Ra₂) in the present exemplary embodiment conform to JISB0601: 2013. A method for measuring the arithmetic average roughness (Ra₁ and Ra₂) is identical with a method for measuring the arithmetic average roughness (Ra₁ and Ra₂) described in Example, and a measuring range is 1 μm×1 μm.

Graphite composite film 1 configured as described above is capable of attaining both a measure against heat and a measure against electromagnetic noise of an electromagnetic device only by being attached to an object to be adhered. That is, graphite composite film 1 that includes graphite layer 40L having excellent thermal conductivity is capable of dissipating heat of the object to be adhered in a plane direction of graphite composite film 1 to decrease a temperature of the object to be adhered. Here, the plane direction refers to a direction perpendicular to a thickness direction of graphite layer 40L, that is, one direction in parallel with a surface of graphite layer 40L. Further, with at least one of the arithmetic average roughness Ra₁ of surface 20A of first metal layer 20 or the arithmetic average roughness Ra₂ of surface 80B of second metal layer 80 being less than or equal to 50 nm, graphite composite film 1 has excellent high-frequency electromagnetic wave shielding performance. This phenomenon is supposed to be caused because, with an increase in frequency of an electromagnetic field (hereinafter, an external electromagnetic field) that attempts to enter first metal layer 20 or second metal layer 80, the external electromagnetic field is, in the present exemplary embodiment, likely to rapidly attenuate in first metal layer 20 or second metal layer 80 even when having entered first metal layer 20 or second metal layer 80, that is, the layer increases a skin effect against the external electromagnetic field. Specifically, when a high-frequency magnetic field (hereinafter, an external magnetic field) enters first metal layer 20 or second metal layer 80, current (hereinafter, eddy current) induced on surface 20A of first metal layer 20 or surface 80B of second metal layer 80 generates a high-frequency magnetic field to cancel the external magnetic field and thus attempts to block the entry of the external magnetic field into first metal layer 20 or second metal layer 80. In the present exemplary embodiment, at least one of the arithmetic average roughness Ra₁ of surface 20A of first metal layer 20 or the arithmetic average roughness Ra₂ of surface 80B of second metal layer 80 is less than or equal to 50 nm. That is, a main factor of the phenomenon is supposed to be that at least one of surface 20A or surface 80B is smooth to have less eddy current loss and thus easily generate a high-frequency magnetic field that attempts to cancel the external magnetic field. As described above, graphite composite film 1 according to the present exemplary embodiment that has excellent high-frequency electromagnetic wave shielding performance is capable of both suppressing entry of electromagnetic noise attributed to the external electromagnetic field into a circuit of an object to be adhered and suppressing electromagnetic emission of the object to be adhered itself. Particularly, the electromagnetic wave shielding performance of graphite composite film 1 according to the present exemplary embodiment is more excellent, according as the frequency of the external electromagnetic field is high, than the shielding performance of such a conventional graphite sheet composite sheet described in PTL 1. When the object to be adhered has electric conductivity, first metal layer 20 and second metal layer 80 are electrically connected to the object to be adhered and are thus earthed, so that the eddy current generated in first metal layer 20 or second metal layer 80 is released (grounded) to the object to be adhered, resulting in graphite composite film 1 according to the present exemplary embodiment that exhibits more excellent electromagnetic wave shielding performance.

In an end surface of graphite composite film 1, end surface 40E of graphite layer 40L is not exposed as shown in FIG. 1B. That is, end surface 40E of graphite layer 40L is covered with first electrically conductive adhesive layer 30L and second electrically conductive adhesive layer 50L. This configuration is capable of preventing both rupture of graphite composite film 1 due to interlayer peeling in graphite layer 40L and powder dropping of graphite layer 40L.

Graphite composite film 1 preferably has a thickness ranging from 15 μm to 800 μm, inclusive. It is possible to measure the thickness of graphite composite film 1 based on an image obtained by observing a section of graphite composite film 1 with a scanning electron microscope (SEM). It is also possible to similarly measure thicknesses of following layers forming graphite composite film 1.

It is possible to use graphite composite film 1 by, for example, peeling first peeling sheet 60 from graphite composite film 1 just before use and attaching graphite composite film 1 to an object to be adhered. Examples of the object to be adhered include an electronic component disposed within a housing of an electronic device. Examples of the electronic component include a rear chassis of a liquid crystal unit, a light-emitting diode (LED) substrate having a light-emitting diode (LED) light source used as, for example, a back light of a liquid crystal image display device, a power amplifier, and a large scale integrated circuit (LSI). As first peeling sheet 60, it is possible to use, for example, one obtained by performing, with, for example, a silicone resin, a peeling treatment on one or both surfaces of paper such as kraft paper, glassine paper, or pure paper; a resin film such as polyethylene, polypropylene (oriented polypropylene (OPP) or cast polypropylene (CPP)), or polyethylene terephthalate (PET); laminated paper obtained by stacking paper and a resin film; or paper filled with, for example, clay or polyvinyl alcohol.

In the present exemplary embodiment, graphite composite film 1 includes second electrically conductive adhesive layer 50L, graphite layer 40L, first electrically conductive adhesive layer 30L, first metal layer 20, and second metal layer 80 stacked in this order. The present exemplary embodiment, however, is not limited to this structure, and graphite composite film 1 may have any structure as long as graphite layer 40L, first electrically conductive adhesive layer 30L, first metal layer 20, and second metal layer 80 are disposed in this order. Further, a layer that does not inhibit the effects of the present disclosed technique may be stacked between these layers. As an example of this structure, a rust-proofing layer may be interposed between first metal layer 20 and first electrically conductive adhesive layer 30L. As the rust-proofing layer, it is possible to use, for example, an organic coating film or a metal coating film. Examples of the organic coating film include a benzotriazole coating film. As a raw material for the benzotriazole coating film, it is possible to use, for example, benzotriazole or a derivative of benzotriazole. As a raw material for the metal coating film, it is possible to use, for example, a pure metal such as zinc, nickel, chromium, titanium, aluminum, gold, silver, or palladium; or an alloy containing these pure metals.

In the present exemplary embodiment, end surface 40E of graphite layer 40L is covered with first electrically conductive adhesive layer 30L and second electrically conductive adhesive layer 50L. The present exemplary embodiment, however, is not limited to this configuration, and end surface 40E of graphite layer 40L may be exposed. In the present exemplary embodiment, end surfaces of first metal layer 20 and second metal layer 80 are exposed as shown in FIG. 1B. The present exemplary embodiment, however, is not limited to this configuration. For example, the end surface of first metal layer 20 may be covered with second metal layer 80. Alternatively, the end surfaces of first metal layer 20 and second metal layer 80 may be covered with a protection film disposed on surface 80B of second metal layer 80.

### (First Metal Layer 20 and Second Meta Layer 80)

Graphite composite film 1 includes first metal layer 20 and second metal layer 80 as shown in FIG. 1A. This configuration makes graphite composite film 1 have an electromagnetic wave shielding function. Further, second metal layer 80 is capable of preventing a flaw on second surface 20B of first metal layer 20. Second metal layer 80 is disposed on second surface 20B of first metal layer 20.

First metal layer 20 contains a first metal. The first metal may be appropriately selected according to a raw material for graphite composite film 1, and it is possible to use, for example, silver, copper, gold, aluminum, magnesium, tungsten, cobalt, zinc, nickel, brass, potassium, lithium, iron, platinum, tin, chromium, lead, or titanium. Among these metals, the first metal is preferably a raw material having high electric conductivity in the raw material for graphite composite film 1 from a viewpoint of improving the electromagnetic wave shielding function of graphite composite film 1. The first metal is more preferably copper from a viewpoint of, for example, having high electric conductivity and being relatively inexpensive.

Second metal layer 80 contains a second metal. As the second metal, it is possible to use, for example, silver, copper, gold, aluminum, magnesium, tungsten, cobalt, zinc, nickel, brass, potassium, lithium, iron, platinum, tin, chromium, lead, titanium, or palladium.

The second metal is preferably at least one metal selected from the group consisting of zinc, nickel, chromium, titanium, aluminum, gold, silver, palladium, and an alloy of these metals. That is, second metal layer 80 preferably contains at least one metal selected from the group consisting of zinc, nickel, chromium, titanium, aluminum, gold, silver, palladium, and an alloy of these metals. These metals have excellent rust-proofing properties, so that second metal layer 80 that contains at least one metal selected from the group consisting of zinc, nickel, chromium, titanium, aluminum, gold, silver, palladium, and an alloy of these metals makes second surface 20B of first metal layer 20 less likely to be corroded. This phenomenon is supposed to be caused because second metal layer 80 that contains a metal having excellent rust-proofing properties makes, for example, components that come from mainly externally, such as moisture and oxygen less likely to reach second surface 20B of first metal layer 20 and thus an electrochemical reaction between the raw material for first metal layer 20 and the components that come from externally less likely to progress.

The second metal is preferably nickel. That is, second metal layer 80 preferably contains nickel. In this case, nickel that has high rust-proofing properties makes first metal layer 20 formed of copper further less likely to be corroded. Further, nickel that has high adhesiveness to copper is capable of improving adhesiveness of second metal layer 80 containing nickel to first metal layer 20 formed of copper. Therefore, even when the end surface of first metal layer 20 is exposed as shown in FIG. 1B, for example, components such as moisture and oxygen are less likely to reach the surface of first metal layer 20 from an interface between second metal layer 80 and first metal layer 20.

An insulating layer for preventing a short-circuit failure may be disposed on surface 80B of second metal layer 80 opposite from a surface on a first metal layer 20-disposed side of second metal layer 80. In this case, it is possible to make a hole on part of the insulating layer and ground graphite layer 40L through the hole. When the insulating layer is disposed directly on first metal layer 20 and the hole is made on the insulating layer for grounding, first metal layer 20 formed of copper causes an electrochemical reaction with, for example, components that come from externally, such as moisture and oxygen, to be corroded. Therefore, when second metal layer 80 contains a metal having excellent rust-proofing properties, second metal layer 80 is capable of preventing first metal layer 20 from being corroded and of grounding graphite layer 40L.

With an arithmetic average roughness of surface 20A on a first electrically conductive adhesive layer 30L-disposed side of first metal layer 20 defined as Ra₁ and an arithmetic average roughness of surface 80B of second metal layer 80 opposite from surface 80A on a first metal layer 20-disposed side of second metal layer 80 defined as Ra₂, at least one of the Ra₁ or the Ra₂ is less than or equal to 50 nm. That is, only the arithmetic average roughness Ra₁ of surface 20A of first metal layer 20 may be less than or equal to 50 nm, only the arithmetic average roughness Ra₂ of surface 80B of second metal layer 80 may be less than or equal to 50 nm, or both the arithmetic average roughness Ra₁ of surface 20A of first metal layer 20 and the arithmetic average roughness Ra₂ of surface 80B of second metal layer 80 may be less than or equal to 50 nm. The eddy current is supposed to be easily induced on one of surface 20A of first metal layer 20 and surface 80B of second metal layer 80 that has a smaller arithmetic average roughness, that is, on a surface having less eddy current loss. This configuration makes graphite composite film 1 have excellent high-frequency electromagnetic wave shielding performance. At least one of the arithmetic average roughness Ra₁ of surface 20A of first metal layer 20 or the arithmetic average roughness Ra₂ of surface 80B of second metal layer 80 is preferably less than or equal to 20 nm, more preferably less than or equal to 10 nm.

With a maximum height roughness of surface 20A on the first electrically conductive adhesive layer 30L-disposed side of first metal layer 20 defined as Rz₁ and a maximum height roughness of surface 80B of second metal layer 80 opposite from surface 80A on the first metal layer 20-disposed side of second metal layer 80 defined as Rz₂, at least one of the Rz₁ or the Rz₂ is preferably less than or equal to 200 nm, more preferably less than or equal to 100 nm. Here, the maximum height roughness (Rz₁ and Rz₂) in the present application conform to JISB0601: 2013. A method for measuring the maximum height roughness (Rz₁ and Rz₂) is identical with a method for measuring the maximum height roughness (Rz₁ and Rz₂) described in Example.

With a ten-point average roughness of surface 20A on the first electrically conductive adhesive layer 30L-disposed side of first metal layer 20 defined as Rzjis₁ and a ten-point average roughness of surface 80B of second metal layer 80 opposite from surface 80A on the first metal layer 20-disposed side of second metal layer 80 defined as Rzjis₂, at least one of the Rzjis₁ or the Rzjis₂ is preferably less than or equal to 100 nm, more preferably less than or equal to 50 nm. Here, the ten-point average roughness (Rzjis₁ and Rzjis₂) in the present application conform to JISB0601: 2013. A method for measuring the ten-point average roughness (Rzjis₁ and Rzjis₂) is identical with a method for measuring the ten-point average roughness (Rzjis₁ and Rzjis₂) described in Example.

Second metal layer 80 preferably has thickness T80 of less than or equal to thickness T20 of first metal layer 20. This configuration enables graphite composite film 1 to both secure flexibility and reduce weight. This configuration enables easy attachment of graphite composite film 1 even to an object to be adhered having a non-flat adhesion surface, to be capable of broadening freedom of disposition of graphite composite film 1. Specifically, first metal layer 20 has thickness T20 ranging preferably from 0.10 μm to 5.00 μm, inclusive, more preferably from 0.50 μm to 2.00 μm, inclusive. Second metal layer 80 has thickness T80 ranging preferably from 0.002 μm to 0.100 μm, inclusive, more preferably from 0.002 μm to 0.040 μm, inclusive.

In the present exemplary embodiment, first metal layer 20 has a solid form as a surface form when viewed in thickness direction T of graphite composite film 1. The present exemplary embodiment, however, is not limited to this form. Exemplary alternatives of the surface form include a mesh form and a wire form. The solid form refers to a form that shows no gap over the surface of first metal layer 20 viewed in thickness direction T of graphite composite film 1.

In the present exemplary embodiment, second metal layer 80 has a solid form as a surface form when viewed in thickness direction T of graphite composite film 1. That is, second metal layer 80 is provided without a gap over a whole region of second surface 20B of first metal layer 20 and second surface 20B of first metal layer 20 is not exposed, when viewed in thickness direction T of graphite composite film 1. In the present exemplary embodiment, however, the surface form of second metal layer 80 is not limited to this form, and second metal layer 80 may have, for example, a mesh form or a wire form.

### (First Electrically Conductive Adhesive Layer 30L)

Graphite composite film 1 includes first electrically conductive adhesive layer 30L as shown in FIG. 1A. This configuration enables first metal layer 20 to be both adhesively fixed and electrically connected to graphite layer 40L.

First electrically conductive adhesive layer 30L includes, as shown in FIG. 1A, first adhesion layer 31, first metal substrate 32, and second adhesion layer 33 stacked in this order. First electrically conductive adhesive layer 30L that includes first metal substrate 32 has excellent electric conductivity. First electrically conductive adhesive layer 30L preferably has a thickness ranging from 2 μm to 300 μm, inclusive. First electrically conductive adhesive layer 30L has a solid form as a surface form when viewed in thickness direction T of graphite composite film 1.

First adhesion layer 31 is formed of an electrically conductive adhesive agent having electric conductivity and adhesion. The electrically conductive adhesive agent contains, for example, a polymer and an electrically conductive filler and may further contain a crosslinking agent, an additive, or a solvent as necessary. As the polymer, it is possible to use, for example, an acrylic polymer, a rubber polymer, a silicone polymer, or a urethane polymer. Among these polymers, an acrylic polymer and a rubber polymer are preferably used from a viewpoint of being less likely to cause peeling by an influence of heat even when graphite composite film 1 is attached to a heat generating member. As the acrylic polymer, it is possible to use one obtained by polymerizing a vinyl monomer such as a (meth)acrylic monomer. As the electrically conductive filler, it is possible to use, for example, a metal filler, a carbon filler, a metal composite filler, a metal oxide filler, or a potassium titanate filler. Examples of a raw material for the metal filler include silver, nickel, copper, tin, aluminum, and stainless steel. As a raw material for the carbon filler, it is possible to use, for example, Ketjen black, acetylene black, or graphite. As a raw material for the metal composite filler, it is possible to use, for example, aluminum-coated glass, nickel-coated glass, silver-coated glass, or nickel-coated carbon. As a raw material for the metal oxide filler, it is possible to use, for example, antimony-doped tin oxide, tin-doped indium oxide, or aluminum-doped zinc oxide. A shape of the electrically conductive filler is not particularly limited, and examples of the shape include powder, flakes, and fibers. As the crosslinking agent, it is possible to use, for example, an isocyanate crosslinking agent, an epoxy crosslinking agent, a chelate crosslinking agent, or an aziridine crosslinking agent. As the additive, it is possible to use a tackifying resin for a purpose of further improving adhesive power of first adhesion layer 31. As the tackifying resin, it is possible to use, for example, a rosin resin; a terpene resin; an aliphatic (C5) or aromatic (C9) petroleum resin; a styrene resin; a phenolic resin; a xylene resin; or a methacrylic resin. First adhesion layer 31 has a thickness ranging preferably from 0.2 μm to 50 μm, inclusive, more preferably from 2 μm to 20 μm, inclusive.

As a raw material for first metal substrate 32, it is possible to use, for example, gold, silver, copper, aluminum, nickel, iron, tin, or an alloy of these metals. Among these metals, the raw material for first metal substrate 32 is preferably aluminum or copper from viewpoints of, for example, flexibility and thermal and electric conductivity, and is further preferably aluminum from a viewpoint of, for example, being less likely to promote corrosion by metal passivation. As the metal substrate formed of aluminum, it is possible to use a hard aluminum substrate formed of hard aluminum or a soft aluminum substrate formed of soft aluminum. The hard aluminum substrate is formed of aluminum foil obtained by subjecting aluminum to rolling. The soft aluminum substrate is formed of aluminum foil obtained by subjecting aluminum to rolling and annealing. As the metal substrate formed of copper, it is possible to use, for example, a substrate formed of electrolytic copper or a substrate formed of rolled copper. First metal substrate 32 has a thickness of preferably less than or equal to 200 μm, more preferably less than or equal to 100 μm.

Second adhesion layer 33 has electric conductivity and adhesion and contains, for example, a polymer and an electrically conductive filler. Second adhesion layer 33 has the same composition as first adhesion layer 31.

In the present exemplary embodiment, first electrically conductive adhesive layer 30L includes, as shown in FIG. 1A, first adhesion layer 31, first metal substrate 32, and second adhesion layer 33 stacked in this order. The present exemplary embodiment, however, is not limited to this structure. As an exemplary alternative, first electrically conductive adhesive layer 30L may be a single layer formed of an electrically conductive resin. In the present exemplary embodiment, second adhesion layer 33 has the same composition as first adhesion layer 31. The present exemplary embodiment, however, is not limited to this configuration, and second adhesion layer 33 may have a different composition from the composition of first adhesion layer 31 as long as second adhesion layer 33 has electric conductivity and adhesion.

### (Graphite Layer 40L)

Graphite composite film 1 includes graphite layer 40L as shown in FIG. 1A. This configuration enables graphite composite film 1 to both efficiently conduct and dissipate heat of an object to be adhered and improve the electromagnetic wave shielding function.

Graphite layer 40L has excellent electric conductivity and thermal conductivity in the plane direction. As a raw material for graphite layer 40L, it is possible to use, for example, a layered carbon crystal graphite or a graphite intercalation compound formed through penetration of a chemical species between layers of graphite as a matrix. Examples of the chemical species include potassium, lithium, bromine, nitric acid, iron(III) chloride, tungsten hexachloride, and arsenic pentafluoride. Graphite layer 40L may be, for example, one obtained by stacking one or a plurality of graphite films. As the graphite film, it is possible to use, for example, a pyrolytic graphite sheet produced by firing a polymer film at high temperature or an expanded graphite sheet produced by an expanded graphite method. Among these graphite sheets, it is preferable to use, as the graphite film, a pyrolytic graphite sheet produced by firing a polymer film at high temperature, from a viewpoint of having high thermal conductivity, being light and flexible, and facilitating processing. As the polymer film, it is possible to use, for example, a heat-resistance aromatic polymer such as a polyimide, a polyamide, or a polyamide-imide. A temperature for firing the polymer film preferably ranges from 2600° C. to 3000° C., inclusive. The expanded graphite method is a method for forming an intercalation compound through treatment of natural graphite with a strong acid such as sulfuric acid, heating and expanding the intercalation compound to produce expanded graphite, and subjecting the expanded graphite to rolling to form the expanded graphite into a sheet. The graphite film preferably has a thickness ranging from 10 μm to 100 μm, inclusive.

The pyrolytic graphite sheet preferably has an a-b plane-direction coefficient of thermal conductivity ranging from 700 W/(m·K) to 1950 W/(m·k), inclusive and preferably has a c-axis-direction coefficient of thermal conductivity ranging from 8 W/(m·K) to 15 W/(m·k), inclusive. The pyrolytic graphite sheet preferably has a density ranging from 0.85 g/cm³ to 2.13 g/cm³, inclusive. As such a pyrolytic graphite sheet, it is possible to use, for example, a “PGS (registered trademark) graphite sheet” manufactured by Panasonic Corporation.

Graphite layer 40L has a thickness ranging preferably from 5 μm to 500 μm, inclusive, more preferably from 10 μm to 200 μm, inclusive. Graphite layer 40L has a solid form as a surface form when viewed in thickness direction T of graphite composite film 1.

### (Second Electrically Conductive Adhesive Layer 50L)

Graphite composite film 1 preferably includes second electrically conductive adhesive layer 50L as shown in FIG. 1A. This configuration enables graphite composite film 1 to be adherent to an object to be adhered, allowing graphite composite film 1 to both easily exhibit excellent heat dissipation properties and electrically connect graphite layer 40L to the object to be adhered. Thus, first metal layer 20 and second metal layer 80 are electrically connected to the object to be adhered, so that when the object to be adhered has electric conductivity, graphite composite film 1 has more excellent electromagnetic wave shielding performance.

Second electrically conductive adhesive layer 50L includes, as shown in FIG. 1A, third adhesion layer 51, second metal substrate 52, and fourth adhesion layer 53 stacked in this order. Second electrically conductive adhesive layer 50L has the same structure as first electrically conductive adhesive layer 30L.

In the present exemplary embodiment, second electrically conductive adhesive layer 50L includes, as shown in FIG. 1A, third adhesion layer 51, second metal substrate 52, and fourth adhesion layer 53 stacked in this order. The present exemplary embodiment, however, is not limited to this structure. As an exemplary alternative, second electrically conductive adhesive layer 50L may be a single layer formed of an electrically conductive resin. In the present exemplary embodiment, second electrically conductive adhesive layer 50L has the same structure as first electrically conductive adhesive layer 30L. The present exemplary embodiment, however, is not limited to this configuration, and second electrically conductive adhesive layer 50L may have a different structure from the structure of first electrically conductive adhesive layer 30L as long as second electrically conductive adhesive layer 50L has electric conductivity and adhesion.

### [First Method for Producing Graphite Composite Film 1 According to First Exemplary Embodiment]

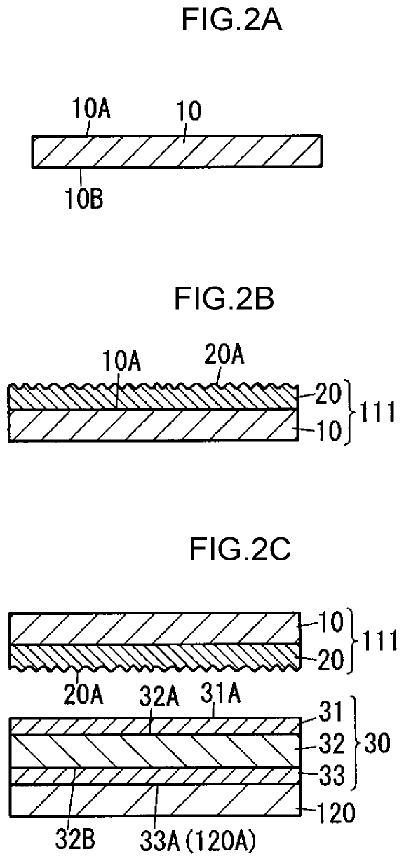

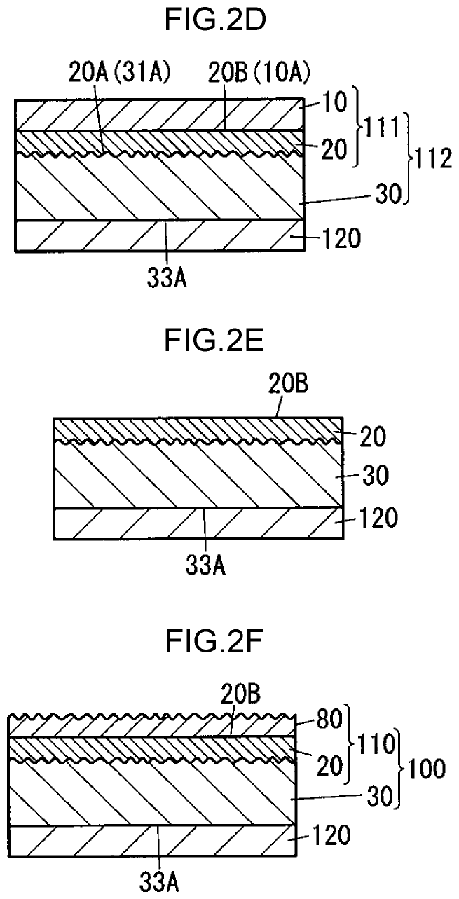

FIGS. 2A to 2F are schematic sectional views for illustrating part of a first method for producing graphite composite film 1 according to the present exemplary embodiment. Specifically, FIGS. 2A to 2F are schematic sectional views for illustrating step (A) of preparing electrically conductive adhesive sheet-attached metal vapor-deposited film 100.

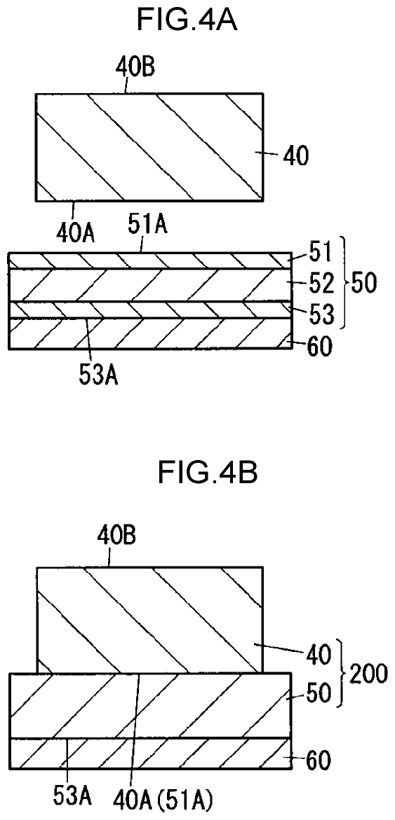

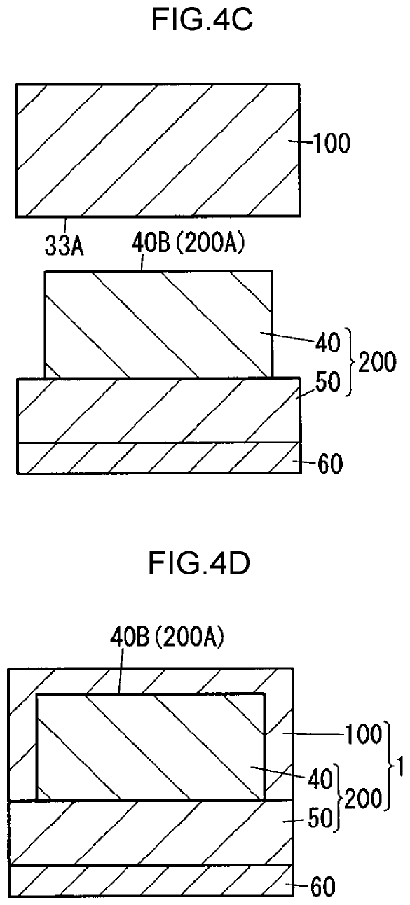

FIGS. 4A to 4D are schematic sectional views for illustrating part of the first method for producing graphite composite film 1 according to the present exemplary embodiment. Specifically, FIGS. 4A and 4B are schematic sectional views for illustrating step (B) of preparing electrically conductive adhesive sheet-attached graphite film 200. FIGS. 4C and 4D are schematic sectional views for illustrating step (C) of subjecting electrically conductive adhesive sheet-attached metal vapor-deposited film 100 and electrically conductive adhesive sheet-attached graphite film 200 to lamination. Constituent members in FIGS. 2A to 2F and 4A to 4D that are identical with the constituent members of the exemplary embodiment shown in FIG. 1A are denoted by identical reference marks and are not described. Graphite film 40 corresponds to graphite layer 40L, first electrically conductive adhesive sheet 30 corresponds to first electrically conductive adhesive layer 30L, and second electrically conductive adhesive sheet 50 corresponds to second electrically conductive adhesive layer 50L.

A method for producing graphite composite film 1 according to the first method includes step (A) of preparing electrically conductive adhesive sheet-attached metal vapor-deposited film 100, step (B) of preparing electrically conductive adhesive sheet-attached graphite film 200, and step (C) of subjecting electrically conductive adhesive sheet-attached metal vapor-deposited film 100 and electrically conductive adhesive sheet-attached graphite film 200 to lamination. Steps (A), (B), and (C) are performed in this order. These steps give graphite composite film 1 that is capable of attaining both a measure against heat and a measure against electromagnetic noise and that has excellent high-frequency electromagnetic wave shielding performance.

Step (A): vapor deposition of a first metal is performed on first surface 10A of protection film 10 having first surface 10A and second surface 10B, to form first metal layer 20 and thus prepare first stacked body 111 (hereinafter step (a1)). First electrically conductive adhesive sheet 30 is disposed on surface 20A of first metal layer 20, thus laminating surface 20A with first electrically conductive adhesive sheet 30, to prepare second stacked body 112 (hereinafter, step (a2)). Protection film 10 of second stacked body 112 is peeled, and then vapor deposition of a second metal is performed on second surface 20B of first metal layer 20 to form second metal layer 80 (hereinafter, step (a3)). Thus, electrically conductive adhesive sheet-attached metal vapor-deposited film 100 is prepared that includes metal vapor-deposited film 110 and first electrically conductive adhesive sheet 30.

Step (B): second electrically conductive adhesive sheet 50 is disposed on first surface 40A of graphite film 40 having first surface 40A and second surface 40B, thus laminating first surface 40A with second electrically conductive adhesive sheet 50.

Step (C): electrically conductive adhesive sheet-attached metal vapor-deposited film 100 and electrically conductive adhesive sheet-attached graphite film 200 are subjected to lamination, with surface 33A of first electrically conductive adhesive sheet 30 and second surface 40B of graphite film 40 disposed so as to overlap one another.

In the present exemplary embodiment, steps (A), (B), and (C) are performed in this order. The present exemplary embodiment, however, is not limited to this order. As an exemplary alternative, the steps may be performed in an order of steps (B), (A), and (C).

### [Step (A)]

Step (A) includes step (a1) of forming first metal layer 20 on protection film 10 and thus preparing first stacked body 111, step (a2) of subjecting first stacked body 111 and first electrically conductive adhesive sheet 30 to lamination to prepare second stacked body 112, and step (a3) of peeling protection film 10 and forming second metal layer 80, that are performed in this order. These steps prepare electrically conductive adhesive sheet-attached metal vapor-deposited film 100 including metal vapor-deposited film 110 as a stacked body of first metal layer 20 and second metal layer 80 and including first electrically conductive adhesive sheet 30.

(Step (a1))

In step (a1), vapor deposition of a first metal is performed on first surface 10A of protection film 10 shown in FIG. 2A to form first metal layer 20 shown in FIG. 2B. Step (a1) gives, as shown in FIG. 2B, first stacked body 111 including protection film 10 and first metal layer 20.

As a raw material for protection film 10, it is possible to use, for example, polyester, polyethylene terephthalate, an olefin resin, a styrene resin, a vinyl chloride resin, polycarbonate, an acrylonitrile-styrene copolymer resin (AS resin), polyacrylonitrile, a butadiene resin, an acrylonitrile-butadiene-styrene copolymer resin (ABS resin), an acrylic resin, polyacetal, polyphenylene ether, a phenol resin, an epoxy resin, a melamine resin, a urea resin, a polyimide, a polysulfide, a polyurethane, a vinyl acetate resin, a fluorine resin, an aliphatic polyamide, a synthetic rubber, an aromatic polyamide, or polyvinyl alcohol. Protection film 10 may further contain a flame retardant, an antistatic agent, an antioxidant, a metal deactivator, a plasticizer, or a lubricant as necessary. Protection film 10 preferably has a thickness ranging from 0.5 μm to 200 μm, inclusive.

Protection film 10 is preferably a releasable film. As the releasable film, it is possible to use, for example, one obtained by applying a release agent to a film. As a raw material for the film used for the releasable film, it is possible to use, for example, polyester, polyethylene terephthalate, an olefin resin, a styrene resin, a vinyl chloride resin, polycarbonate, an acrylonitrile-styrene copolymer resin (AS resin), polyacrylonitrile, a butadiene resin, an acrylonitrile-butadiene-styrene copolymer resin (ABS resin), an acrylic resin, polyacetal, polyphenylene ether, a phenol resin, an epoxy resin, a melamine resin, a urea resin, a polyimide, a polysulfide, a polyurethane, a vinyl acetate resin, a fluorine resin, an aliphatic polyamide, a synthetic rubber, an aromatic polyamide, or polyvinyl alcohol. As the release agent, it is possible to use, for example, silicone. Protection film 10 that is a releasable film facilitates peeling of protection film 10.

A method for performing the vapor deposition of the first metal is preferably a vacuum vapor deposition method. As a method for setting the arithmetic average roughness Ra₁ of surface 20A of first metal layer 20 at less than or equal to 50 nm, a method is exemplified that includes appropriately adjusting, for example, a degree of vacuum and a temperature in a vacuum furnace.

Step (a1) may continuously form first stacked body 111 by, for example, performing vapor deposition of the first metal on first surface 10A of elongated protection film 10.

(Step (a2))

In step (a2), first electrically conductive adhesive sheet 30 is, as shown in FIG. 2C, disposed on surface 20A of first stacked body 111, thus laminating surface 20A with first electrically conductive adhesive sheet 30. At this time, second peeling sheet 120 is, as shown in FIG. 2C, fitted to surface 33A of first electrically conductive adhesive sheet 30 from a viewpoint of easy handling. Step (a2) gives, as shown in FIG. 2D, second stacked body 112 including first stacked body 111 and first electrically conductive adhesive sheet 30.

Examples of a method for producing second peeling sheet 120-fitted first electrically conductive adhesive sheet 30 shown in FIG. 2C include a method indicated below. That is, the method includes a step of applying an electrically conductive adhesive agent onto a surface of a third peeling sheet to form first adhesion layer 31. The method includes a step of applying an electrically conductive adhesive agent onto surface 120A of second peeling sheet 120 and drying the electrically conductive adhesive agent to form second adhesion layer 33. The method includes a step of attaching first adhesion layer 31 and second adhesion layer 33 respectively to first surface 32A and second surface 32B of first metal substrate 32 having first surface 32A and second surface 32B, to form a laminated film, and curing the laminated film and then peeling the third peeling sheet from the laminated film. Examples of a method for applying the electrically conductive adhesive agent include a method with use of, for example, a roll coater or a die coater. When the electrically conductive adhesive agent contains a solvent, the drying is preferably performed in an environment with a temperature approximately ranging from 50° C. to 120° C. to remove the solvent. As a treatment condition for the curing, a treatment temperature preferably ranges from 15° C. to 50° C., inclusive, and a treatment period preferably ranges from 48 hours to 168 hours, inclusive. Second peeling sheet 120 and the third peeling sheet have the same structure as first peeling sheet 60.

Examples of a method for subjecting first stacked body 111 and first electrically conductive adhesive sheet 30 to lamination include a method for disposing first stacked body 111 and first electrically conductive adhesive sheet 30 such that surface 20A of first stacked body 111 faces surface 31A of first electrically conductive adhesive sheet 30, and making surface 20A of first stacked body 111 adherent to surface 31A of first electrically conductive adhesive sheet 30 by pressure contact.

Step (a2) may continuously form second stacked body 112 by, for example, sending elongated first stacked body 111 and elongated first electrically conductive adhesive sheet 30 out to between a pair of rolls and sandwiching first stacked body 111 and first electrically conductive adhesive sheet 30 between the pair of rolls for surface contact to perform lamination.

In the present exemplary embodiment, second peeling sheet 120 is fitted to surface 33A of first electrically conductive adhesive sheet 30. The present exemplary embodiment, however, is not limited to this configuration, and second peeling sheet 120 need not be fitted to surface 33A of first electrically conductive adhesive sheet 30.

(Step (a3))

In step (a3), protection film 10 is peeled from second stacked body 112 as shown in FIG. 2E, and vapor deposition of a second metal is performed on second surface 20B of first metal layer 20 to form second metal layer 80 shown in FIG. 2F. Step (a3) gives, as shown in FIG. 2F, electrically conductive adhesive sheet-attached metal vapor-deposited film 100 including metal vapor-deposited film 110 and first electrically conductive adhesive sheet 30.

The method for performing the vapor deposition of the second metal is preferably a vacuum vapor deposition method. As a method for setting the arithmetic average roughness Ra₂ of surface 80B of second metal layer 80 at less than or equal to 50 nm, a method is exemplified that includes appropriately adjusting, for example, a degree of vacuum and a temperature in a vacuum furnace.

In the present exemplary embodiment, step (A) includes steps (a1), (a2), and (a3). The present exemplary embodiment, however, is not limited to this order of the steps and employs, for example, a method for peeling protection film 10 and forming second metal layer 80 after step (a1) to manufacture metal vapor-deposited film 110 and then subjecting metal vapor-deposited film 110 and first electrically conductive adhesive sheet 30 to lamination. Alternatively, electrically conductive adhesive sheet-attached metal vapor-deposited film 100 may be manufactured by, for example, a method for peeling protection film 10 after step (a1), subjecting first metal layer 20 and first electrically conductive adhesive sheet 30 to lamination, and then forming second metal layer 80.

### [Step (B)]

In step (B), second electrically conductive adhesive sheet 50 is, as shown in FIG. 4A, disposed on first surface 40A of graphite film 40 having first surface 40A and second surface 40B, thus laminating first surface 40A with second electrically conductive adhesive sheet 50. At this time, first peeling sheet 60 is, as shown in FIG. 4A, fitted to surface 53A of second electrically conductive adhesive sheet 50 from a viewpoint of easy handling. Step (B) gives electrically conductive adhesive sheet-attached graphite film 200 shown in FIG. 4B.

Examples of a method for producing first peeling sheet 60-fitted second electrically conductive adhesive sheet 50 shown in FIG. 4A include the same method as the above-mentioned method for producing second peeling sheet 120-fitted first electrically conductive adhesive sheet 30 shown in FIG. 2D.

Examples of a method for subjecting graphite film 40 and second electrically conductive adhesive sheet 50 to lamination include a method for disposing second electrically conductive adhesive sheet 50 as shown in FIG. 4A such that surface 51A of second electrically conductive adhesive sheet 50 is directed upward and placing graphite film 40 that has been cut into a prescribed dimension on surface 51A of second electrically conductive adhesive sheet 50.

The dimension of cut graphite film 40 may be any dimension as long as entire graphite film 40 is, as shown in FIG. 4D, covered with electrically conductive adhesive sheet-attached metal vapor-deposited film 100 and electrically conductive adhesive sheet-attached graphite film 200. Covering entire graphite film 40 with electrically conductive adhesive sheet-attached metal vapor-deposited film 100 and electrically conductive adhesive sheet-attached graphite film 200 is capable of preventing rupture of graphite composite film 1 due to interlayer peeling in graphite layer 40L and preventing powder dropping of graphite layer 40L.

Step (B) may continuously produce electrically conductive adhesive sheet-attached graphite film 200 by, for example, continuously sending second electrically conductive adhesive sheet 50 out to a laminate producing step and continuously placing, with a prescribed interval, cut graphite film 40 on surface 51A of second electrically conductive adhesive sheet 50.

In the present exemplary embodiment, cut graphite film 40 is placed on surface 51A of second electrically conductive adhesive sheet 50, thus laminating graphite film 40 with second electrically conductive adhesive sheet 50. The present exemplary embodiment, however, is not limited to this lamination process, and the lamination may be performed by continuously sending each of elongated graphite film 40 and elongated second electrically conductive adhesive sheet 50 out to between a pair of rolls and sandwiching graphite film 40 and second electrically conductive adhesive sheet 50 between the pair of rolls for surface contact.

### [Step (C)]

In step (C), electrically conductive adhesive sheet-attached metal vapor-deposited film 100 and electrically conductive adhesive sheet-attached graphite film 200 are, as shown in FIG. 4C, subjected to lamination, with surface 33A of first electrically conductive adhesive sheet 30 and second surface 40B of graphite film 40 disposed so as to overlap one another. At this time, second peeling sheet 120 has been peeled as shown in FIG. 4C. First peeling sheet 60 is kept fitted from a viewpoint of easy handling of graphite composite film 1. Step (C) gives graphite composite film 1 shown in FIG. 4D.

Examples of a method for subjecting electrically conductive adhesive sheet-attached metal vapor-deposited film 100 and electrically conductive adhesive sheet-attached graphite film 200 to lamination include a method shown in FIG. 4C. That is, a method is exemplified that includes disposing electrically conductive adhesive sheet-attached graphite film 200 such that surface 200A on a graphite film 40-disposed side is directed upward and placing electrically conductive adhesive sheet-attached metal vapor-deposited film 100 on surface 200A of electrically conductive adhesive sheet-attached graphite film 200 so as to cover entire graphite film 40.

Step (C) may continuously produce graphite composite film 1 by, for example, sending elongated electrically conductive adhesive sheet-attached metal vapor-deposited film 100 and elongated electrically conductive adhesive sheet-attached graphite film 200 out to between a pair of rolls, sandwiching electrically conductive adhesive sheet-attached metal vapor-deposited film 100 and electrically conductive adhesive sheet-attached graphite film 200 between the pair of rolls for surface contact to perform lamination, and cutting a resultant graphite composite film into a necessary size.

The present exemplary embodiment includes steps (A), (B), and (C). The present exemplary embodiment, however, is not limited to this stacking order, and following methods are exemplified. A method is exemplified that includes subjecting first stacked body 111, first electrically conductive adhesive sheet 30, graphite film 40, and second electrically conductive adhesive sheet 50 simultaneously to lamination, then peeling protection film 10, and forming second metal layer 80 to produce graphite composite film 1. Another method is exemplified that includes subjecting first electrically conductive adhesive sheet 30, graphite film 40, and second electrically conductive adhesive sheet 50 to lamination to give a laminated film and subjecting the obtained laminated film and metal vapor-deposited film 110 to lamination to produce graphite composite film 1. Another method is exemplified that includes subjecting metal vapor-deposited film 110, first electrically conductive adhesive sheet 30, and graphite film 40 to lamination to give a laminated film and subjecting the obtained laminated film and second electrically conductive adhesive sheet 50 to lamination to produce graphite composite film 1.

### [Second Method for Producing Graphite Composite Film 1 According to First Exemplary Embodiment]

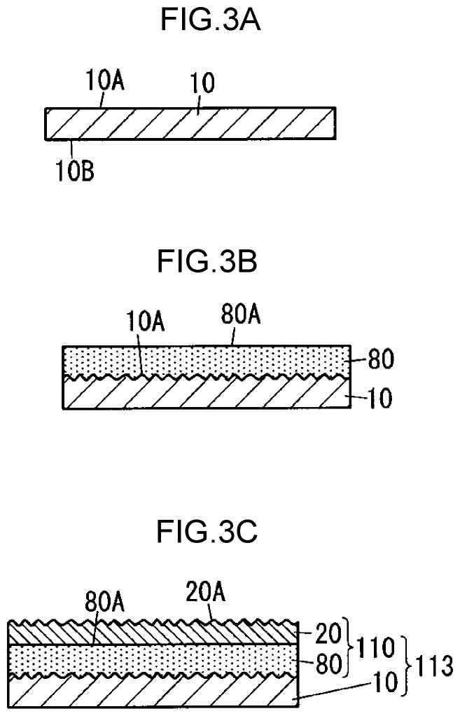

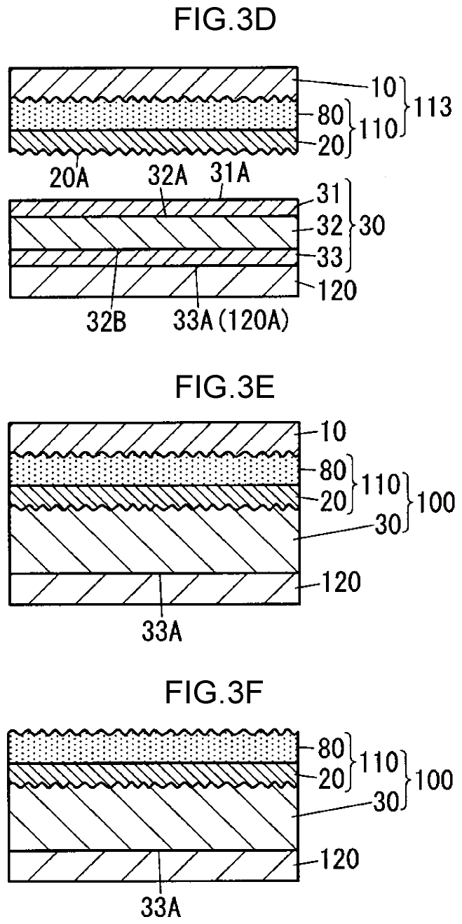

FIGS. 3A to 3F are schematic sectional views for illustrating part of a second method for producing graphite composite film 1 according to the present exemplary embodiment. Specifically, FIGS. 3A to 3F are schematic sectional views for illustrating step (A) of preparing electrically conductive adhesive sheet-attached metal vapor-deposited film 100.

FIGS. 4A to 4D are schematic sectional views for illustrating part of the second method for producing graphite composite film 1 according to the present exemplary embodiment. Specifically, FIGS. 4A and 4B are schematic sectional views for illustrating step (B) of preparing electrically conductive adhesive sheet-attached graphite film 200. FIGS. 4C and 4D are schematic sectional views for illustrating step (C) of subjecting electrically conductive adhesive sheet-attached metal vapor-deposited film 100 and electrically conductive adhesive sheet-attached graphite film 200 to lamination. Constituent members in FIGS. 3A to 3F and 4A to 4D that are identical with the constituent members of the exemplary embodiment shown in FIG. 1A are denoted by identical reference marks and are not described. Specifically, graphite film 40 corresponds to graphite layer 40L, first electrically conductive adhesive sheet 30 corresponds to first electrically conductive adhesive layer 30L, and second electrically conductive adhesive sheet 50 corresponds to second electrically conductive adhesive layer 50L.

The second method for producing graphite composite film 1 according to the present exemplary embodiment includes step (A) of preparing electrically conductive adhesive sheet-attached metal vapor-deposited film 100, step (B) of preparing electrically conductive adhesive sheet-attached graphite film 200, and step (C) of subjecting electrically conductive adhesive sheet-attached metal vapor-deposited film 100 and electrically conductive adhesive sheet-attached graphite film 200 to lamination. Steps (A), (B), and (C) are performed in this order. These steps give graphite composite film 1 that is capable of attaining both a measure against heat and a measure against electromagnetic noise and that has excellent high-frequency electromagnetic wave shielding performance.

Step (A): vapor deposition of a second metal and a first metal is performed in this order on first surface 10A of protection film 10 having first surface 10A and second surface 10B, to prepare stacked body 113 of metal vapor-deposited film 110 and protection film 10, with metal vapor-deposited film 110 including second metal layer 80 that contains the second metal and including first metal layer 20 that contains the first metal (hereinafter, step (a1)). First electrically conductive adhesive sheet 30 is disposed on surface 20A of first metal layer 20 in stacked body 113, thus laminating surface 20A with first electrically conductive adhesive sheet 30, and protection film 10 is peeled (hereinafter, step (a2)). Thus, electrically conductive adhesive sheet-attached metal vapor-deposited film 100 is prepared that includes metal vapor-deposited film 110 and first electrically conductive adhesive sheet 30.

Step (B): second electrically conductive adhesive sheet 50 is disposed on first surface 40A of graphite film 40 having first surface 40A and second surface 40B, thus laminating first surface 40A with second electrically conductive adhesive sheet 50.

Step (C): electrically conductive adhesive sheet-attached metal vapor-deposited film 100 and electrically conductive adhesive sheet-attached graphite film 200 are subjected to lamination, with surface 33A of first electrically conductive adhesive sheet 30 and second surface 40B of graphite film 40 disposed so as to overlap one another.

In the present exemplary embodiment, steps (A), (B), and (C) are performed in this order. The present exemplary embodiment, however, is not limited to this order. As an exemplary alternative, the steps may be performed in an order of steps (B), (A), and (C).

Steps (B) and (C) in the present exemplary embodiment are the same as steps (B) and (C) in the first method and are thus not described.

### [Step (A)]

Step (A) includes step (a1) of forming second metal layer 80 and first metal layer 20 and thus preparing stacked body 113 and step (a2) of subjecting stacked body 113 and first electrically conductive adhesive sheet 30 to lamination and then peeling protection film 10, that are performed in this order. These steps prepare electrically conductive adhesive sheet-attached metal vapor-deposited film 100 including metal vapor-deposited film 110 as a stacked body of first metal layer 20 and second metal layer 80 and including first electrically conductive adhesive sheet 30.

(Step (a1))

In step (a1), vapor deposition of a second metal is performed on first surface 10A of protection film 10 shown in FIG. 3A to form second metal layer 80 shown in FIG. 3B, and vapor deposition of a first metal is performed on surface 80A of second metal layer 80 to form first metal layer 20 shown in FIG. 3C. Step (a1) gives, as shown in FIG. 3C, stacked body 113 including protection film 10 and metal vapor-deposited film 110.

Protection film 10 used in the present method may be the same as protection film 10 used in the first method.

The method for performing the vapor deposition of the second metal is preferably a vacuum vapor deposition method. As a method for setting the arithmetic average roughness Ra₂ of surface 80B of second metal layer 80 at less than or equal to 50 nm, a method is exemplified that includes appropriately adjusting, for example, a degree of vacuum and a temperature in a vacuum furnace. When second metal layer 80 is formed by a vacuum vapor deposition method, a surface state of surface 80B of second metal layer 80 does not completely conform to a surface state of first surface 10A of protection film 10, and the arithmetic average roughness Ra₂ of surface 80B of second metal layer 80 tends to be smaller than an arithmetic average roughness (Ra) of first surface 10A of protection film 10.

A method for performing the vapor deposition of the first metal is preferably a vacuum vapor deposition method. As a method for setting the arithmetic average roughness Ra₁ of surface 20A of first metal layer 20 at less than or equal to 50 nm, a method is exemplified that includes appropriately adjusting, for example, a degree of vacuum and a temperature in a vacuum furnace.

Step (a1) may continuously produce second metal layer 80 and first metal layer 20 by, for example, continuously sending elongated protection film 10 out to a producing step of performing the vapor deposition of the second metal, thus allowing elongated protection film 10 to go through the producing step of performing the vapor deposition of the second metal and a producing step of performing the vapor deposition of the first metal in this order.

(Step (a2))

In step (a2), first electrically conductive adhesive sheet 30 is disposed on surface 20A of first metal layer 20 in stacked body 113, thus laminating surface 20A with first electrically conductive adhesive sheet 30. At this time, second peeling sheet 120 is, as shown in FIG. 3D, fitted to surface 33A of first electrically conductive adhesive sheet 30 from a viewpoint of easy handling. Thereafter, protection film 10 is peeled, and electrically conductive adhesive sheet-attached metal vapor-deposited film 100 shown in FIG. 3F is obtained that includes metal vapor-deposited film 110 and first electrically conductive adhesive sheet 30.

A method for producing second peeling sheet 120-fitted first electrically conductive adhesive sheet 30 shown in FIG. 3D may be the same as the method for producing first electrically conductive adhesive sheet 30 shown in FIG. 2D.

Examples of a method for subjecting stacked body 113 and first electrically conductive adhesive sheet 30 to lamination include a method for disposing stacked body 113 and first electrically conductive adhesive sheet 30 such that surface 20A of stacked body 113 faces surface 31A of first electrically conductive adhesive sheet 30, and making surface 20A of stacked body 113 adherent to surface 31A of first electrically conductive adhesive sheet 30 by pressure contact.

In step (a2), the lamination may be performed by, for example, sending stacked body 113 and elongated first electrically conductive adhesive sheet 30 out to between a pair of rolls and sandwiching stacked body 113 and first electrically conductive adhesive sheet 30 between the pair of rolls for surface contact.

In the present exemplary embodiment, second peeling sheet 120 is fitted to surface 33A of first electrically conductive adhesive sheet 30. The present exemplary embodiment, however, is not limited to this configuration, and second peeling sheet 120 need not be fitted to surface 33A of first electrically conductive adhesive sheet 30.

In the present exemplary embodiment, step (A) includes steps (a1) and (a2). The present exemplary embodiment, however, is not limited to this order of the steps and may employ, for example, a method for peeling protection film 10 from stacked body 113 after step (a1) to manufacture metal vapor-deposited film 110 and then subjecting metal vapor-deposited film 110 and first electrically conductive adhesive sheet 30 to lamination, to manufacture electrically conductive adhesive sheet-attached metal vapor-deposited film 100.

The present exemplary embodiment includes steps (A), (B), and (C). The present exemplary embodiment, however, is not limited to this stacking order, and following methods are exemplified. A method is exemplified that includes subjecting stacked body 113, first electrically conductive adhesive sheet 30, graphite film 40, and second electrically conductive adhesive sheet 50 simultaneously to lamination and then peeling protection film 10 to produce graphite composite film 1. Another method is exemplified that includes subjecting first electrically conductive adhesive sheet 30, graphite film 40, and second electrically conductive adhesive sheet 50 to lamination to give a laminated film and subjecting the obtained laminated film and metal vapor-deposited film 110 to lamination to produce graphite composite film 1. Another method is exemplified that includes subjecting metal vapor-deposited film 110, first electrically conductive adhesive sheet 30, and graphite film 40 to lamination to give a laminated film and subjecting the obtained laminated film and second electrically conductive adhesive sheet 50 to lamination to produce graphite composite film 1.

### Example

Hereinafter, the present exemplary embodiment is specifically described by way of an example.

### [Measurement of Surface States]

A scanning probe microscope (“SPM-9600” manufactured by SHIMADZU CORPORATION) was used for measuring the arithmetic average roughness (Ra), the maximum height roughness (Rz), and the ten-point average roughness (Rzjis) of a metal layer. Specifically, a sample to be measured was fixed to a metal plate, three surface measurement locations A, B, and C were selected, with a measuring range set at 1 μm×1 μm or 10 μm×10 μm, and each of the locations was measured for the arithmetic average roughness (Ra), the maximum height roughness (Rz), and the ten-point average roughness (Rzjis) by surface analysis software built in the scanning probe microscope. An average value of measured values at these three locations was defined as the arithmetic average roughness (Ra), the maximum height roughness (Rz), and the ten-point average roughness (Rzjis).

### Example 1

[Step (A)]

(Step (a1))

As protection film 10, a polyester film (“CX40” manufactured by Toray Industries, Inc., main raw material: PET, thickness: 6 μm) was prepared. This polyester film was disposed in a vacuum case and a second metal was attached to or deposited on first surface 10A of protection film 10 with use of nickel (electrolytic nickel manufactured by Sumitomo Metal Mining Co., Ltd.) as the second metal, while the degree of vacuum and the temperature in vacuum vapor deposition were adjusted, to form second metal layer 80 (thickness: 40 nm). Next, a first metal was attached to or deposited on surface 80A of second metal layer 80 with use of copper (oxygen-free copper manufactured by Hitachi Metals Neomaterial, Ltd.) as the first metal, while the degree of vacuum and the temperature in vacuum vapor deposition were adjusted again, to form first metal layer 20 (thickness: 1 μm). These procedures gave stacked body 113 shown in FIG. 3C. Surface 20A of first metal layer 20 in obtained stacked body 113 was measured for the surface states (Ra₁, Rz₁, and Rzjis₁). Table 1 shows results of the measurement.

(Step (a2))

As second peeling sheet 120-fitted first electrically conductive adhesive sheet 30, a sheet was prepared that was obtained by peeling a peeling sheet from one surface 31A of an electrically conductive double coated adhesive sheet (DAITAC (registered trademark) “#8506ADW-10-H2” manufactured by DIC Corporation, metal substrate: substrate formed of aluminum, thickness: 10 μm).

As shown in FIG. 3D, stacked body 113 and first electrically conductive adhesive sheet 30 were disposed such that surface 20A of stacked body 113 faces surface 31A of first electrically conductive adhesive sheet 30, and surface 20A of stacked body 113 was made adherent to surface 31A of first electrically conductive adhesive sheet 30 by pressure contact. Next, the polyester film as protection film 10 was peeled by pressing a peeling roller against the polyester film. These procedures gave electrically conductive adhesive sheet-attached metal vapor-deposited film 100 shown in FIG. 3F. Surface 80B of second metal layer 80 in obtained electrically conductive adhesive sheet-attached metal vapor-deposited film 100 was measured for the surface states (Ra₂, Rz₂, and Rzjis₂). Table 1 shows results of the measurement.

### [Step (B)]

As first peeling sheet 60-fitted second electrically conductive adhesive sheet 50, a sheet was prepared that was obtained by peeling a peeling sheet from one surface 51A from an electrically conductive double coated adhesive sheet, i.e., the same product as first electrically conductive adhesive sheet 30. As graphite film 40, a graphite film (“PGS (registered trademark) graphite sheet” manufactured by Panasonic Corporation, thickness: 25 μm) cut into a size of 10 cm×12 cm was prepared.

As shown in FIG. 4A, second electrically conductive adhesive sheet 50 was disposed such that surface 51A of second electrically conductive adhesive sheet 50 was directed upward, and graphite film 40 was placed on surface 51A of second electrically conductive adhesive sheet 50. These procedures gave electrically conductive adhesive sheet-attached graphite film 200 shown in FIG. 4B.

### [Step (C)]

As shown in FIG. 4C, electrically conductive adhesive sheet-attached graphite film 200 was disposed such that surface 200A on a graphite film 40-disposed side was directed upward, and electrically conductive adhesive sheet-attached metal vapor-deposited film 100 was placed on surface 200A of electrically conductive adhesive sheet-attached graphite film 200 so as to cover entire graphite film 40 and was cut into a size of 10 cm×12 cm. These procedures gave graphite composite film 1 shown in FIG. 4D.

### Comparative Example 11

An electrolytic copper foil (“F2-WS” manufactured by Furukawa Electric Co., Ltd.) was prepared as first metal layer 20. Surface 20A of the electrolytic copper foil was measured for the surface states (Ra₁, Rz₁, and Rzjis₁). Table 2 shows results of the measurement.

Next, as second peeling sheet 120-fitted first electrically conductive adhesive sheet 30, a sheet was prepared that was obtained by peeling a peeling sheet from one surface 31A of an electrically conductive double coated adhesive sheet (DAITAC (registered trademark) “#8506ADW-10-H2” manufactured by DIC Corporation, metal substrate: substrate formed of aluminum, thickness: 10 μm).

The electrolytic copper foil and first electrically conductive adhesive sheet 30 were disposed such that surface 20A of the electrolytic copper foil faces surface 31A of first electrically conductive adhesive sheet 30, and surface 20A of the electrolytic copper foil was made adherent to surface 31A of first electrically conductive adhesive sheet 30 by pressure contact. These procedures gave an electrically conductive adhesive sheet-attached electrolytic copper foil. Second surface 20B of the electrolytic copper foil opposite from surface 20A of the electrolytic copper foil in the obtained electrically conductive adhesive sheet-attached electrolytic copper foil was measured for the surface states (Ra₂, Rz₂, and Rzjis₂). Table 2 shows results of the measurement.

Graphite composite film 1 was obtained in the same manner as Example 1 except that the electrically conductive adhesive sheet-attached electrolytic copper foil was used in place of electrically conductive adhesive sheet-attached metal vapor-deposited film 100.

### [Measurement Test for Electromagnetic Wave Shielding Performance]

Samples obtained by peeling first peeling sheet 60 from obtained graphite composite films 1 were measured for the electromagnetic field shielding performance at a frequency range of 8 MHz in accordance with a coaxial line method.

Table 3 shows results of the measurement for the electromagnetic field shielding performance of the samples.

TABLE 1

| | Example 1 | | | | | | | |
|---|---|---|---|---|---|---|---|---|
| | Measurement | Measurement | Measurement | Average | Measurement | Measurement | Measurement | Average |
| | location A | location B | location C | value | location A | location B | location C | value |
| | Measuring range | | | | | | | |
| | 10 μm × 10 μm | | | | 1 μm × 1 μm | | | |
| Ra₁ (nm) | 5.7 | 8.1 | 13.0 | 8.9 | 4.8 | 4.2 | 6.2 | 5.0 |
| Rz₁ (nm) | 83 | 138 | 143 | 121 | 56 | 42 | 68 | 55 |
| Rzjis₁ (nm) | 40 | 67 | 68 | 58 | 28 | 21 | 34 | 28 |
| Ra₂ (nm) | 4.7 | 9.6 | 10.1 | 8.1 | 2.2 | 2.0 | 1.9 | 2.0 |
| Rz₂ (nm) | 81 | 61 | 127 | 90 | 28 | 22 | 21 | 24 |
| Rzjis₂ (nm) | 35 | 28 | 60 | 41 | 13 | 11 | 10 | 12 |

TABLE 2

| | Comparative Example 1 | | | | | | | |
|---|---|---|---|---|---|---|---|---|
| | Measurement | Measurement | Measurement | Average | Measurement | Measurement | Measurement | Average |
| | location A | location B | location C | value | location A | location B | location C | value |
| | Measuring range | | | | | | | |
| | 10 μm × 10 μm | | | | 1 μm × 1 μm | | | |
| Ra₁ (nm) | 73.9 | 58.6 | 82.1 | 71.5 | 62.5 | 59.8 | 76.0 | 66.1 |
| Rz₁ (nm) | 699 | 519 | 761 | 660 | 352 | 269 | 420 | 347 |
| Rzjis₁ (nm) | 344 | 248 | 369 | 320 | 192 | 152 | 223 | 189 |
| Ra₂ (nm) | 102.2 | 49.3 | 59.2 | 70.2 | 62.1 | 58.5 | 79.2 | 66.6 |
| Rz₂ (nm) | 623 | 592 | 778 | 664 | 332 | 301 | 442 | 358 |
| Rzjis₂ (nm) | 295 | 265 | 332 | 297 | 162 | 148 | 230 | 180 |

TABLE 3

| | Arithmetic | Arithmetic | Electromagnetic |
|---|---|---|---|
| | average | average | field shielding |
| | roughness Ra₁ | roughness Ra₂ | performance at 8 GHz |
| | (nm) | (nm) | (dB) |
| Example 1 | 5.0 | 2.0 | 105 |
| Comparative | 66.1 | 66.6 | 91 |
| Example 1 | | | |

### Second Exemplary Embodiment

Hereinafter, a second exemplary embodiment of the present disclosure is described.

### [Graphite Composite Film 1 According to Present Exemplary Embodiment]

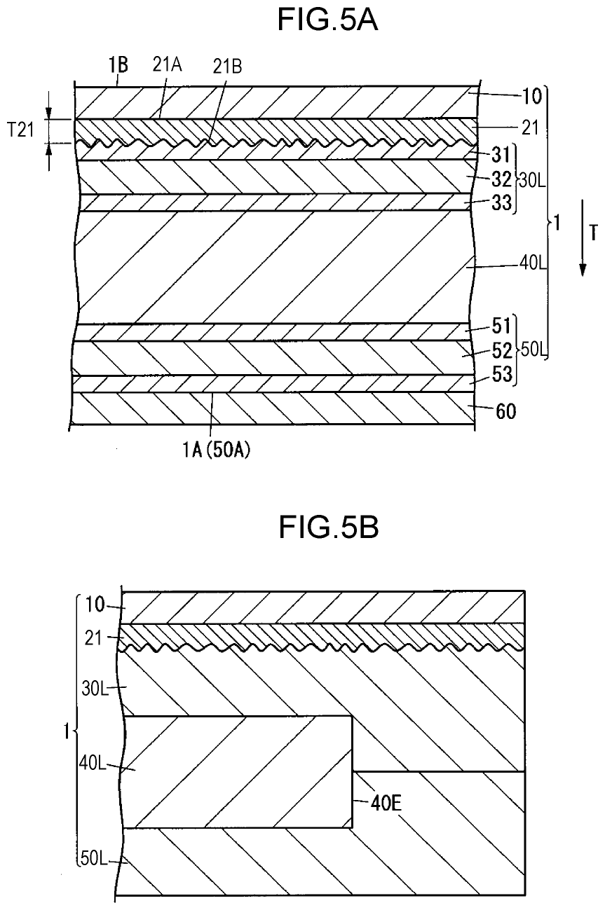

FIG. 5A is a schematic sectional view of a main portion of graphite composite film 1 according to a second exemplary embodiment. FIG. 5B is a schematic sectional view of an end portion of graphite composite film 1.

Graphite composite film 1 according to the present exemplary embodiment includes, as shown in FIG. 5A, second electrically conductive adhesive layer 50L, graphite layer 40L, first electrically conductive adhesive layer 30L, metal layer 21 that contains a first metal and has first surface 21A and second surface 21B, and protection film 10 in this order, with protection film 10 disposed to position on a side of first surface 21A of metal layer 21. An arithmetic average roughness (Ra) of second surface 21B of metal layer 21 is less than or equal to 50 nm. Further, first peeling sheet 60 is fitted to surface 50A of second electrically conductive adhesive layer 50L. Here, the arithmetic average roughness (Ra) in the present application conforms to JISB0601: 2013. A method for measuring the arithmetic average roughness (Ra) is identical with a method for measuring the arithmetic average roughness (Ra) described in Example, and a measuring range is 1 μm×1 μm.

Graphite composite film 1 configured as described above is capable of attaining both a measure against heat and a measure against electromagnetic noise of an electronic device only by being attached to an object to be adhered. That is, graphite composite film 1 that includes graphite layer 40L having excellent thermal conductivity is capable of dissipating heat of the object to be adhered in a plane direction of graphite composite film 1 to decrease a temperature of the object to be adhered. Graphite composite film 1 includes metal layer 21 whose second surface 21B has an arithmetic average roughness (Ra) of less than or equal to 50 nm, to have excellent high-frequency electromagnetic wave shielding performance. This phenomenon is supposed to be caused because, with an increase in frequency of an electromagnetic field (hereinafter, an external electromagnetic field) that enters metal layer 21, the external electromagnetic field is, in the present exemplary embodiment, likely to rapidly attenuate in metal layer 21 even when having entered metal layer 21, that is, metal layer 21 increases a skin effect against the external electromagnetic field. Specifically, when a high-frequency magnetic field (hereinafter, an external magnetic field) enters metal layer 21, current (hereinafter, eddy current) induced on a surface of metal layer 21 generates a high-frequency magnetic field to cancel the external magnetic field and thus attempts to block the entry of the external magnetic field into metal layer 21. A main factor of the phenomenon is supposed to be that graphite composite film 1 according to the present exemplary embodiment includes second surface 21B that has an arithmetic average roughness (Ra) of less than or equal to 50 nm and that is smooth, to have less eddy current loss and thus easily generate a high-frequency magnetic field that attempts to cancel the external magnetic field. As described above, graphite composite film 1 according to the present exemplary embodiment that has excellent high-frequency electromagnetic wave shielding performance is capable of both suppressing entry of electromagnetic noise due to the external electromagnetic field into a circuit of an object to be adhered and suppressing electromagnetic emission of the object to be adhered itself. Particularly, the electromagnetic wave shielding performance of graphite composite film 1 according to the present exemplary embodiment is more excellent, according as the frequency of the external electromagnetic field is high, than the shielding performance of such a conventional graphite sheet composite sheet described in PTL 1. When the object to be adhered has electric conductivity, metal layer 21 is electrically connected to the object to be adhered and is thus earthed, so that the eddy current generated in metal layer 21 is released (grounded) to the object to be adhered, resulting in graphite composite film 1 exhibiting more excellent electromagnetic wave shielding performance. Here, the plane direction refers to a direction perpendicular to a thickness direction of graphite layer 40L, that is, one direction in parallel with a surface of graphite layer 40L.

In an end surface of graphite composite film 1, end surface 40E of graphite layer 40L is not exposed as shown in FIG. 5B. That is, end surface 40E of graphite layer 40L is covered with first electrically conductive adhesive layer 30L and second electrically conductive adhesive layer 50L. This configuration is capable of preventing both rupture of graphite composite film 1 attributed to interlayer peeling in graphite layer 40L and powder dropping of graphite layer 40L.

Graphite composite film 1 preferably has a thickness ranging from 15 μm to 800 μm, inclusive. It is possible to measure the thickness of graphite composite film 1 based on an image obtained by observing a section of graphite composite film 1 with a scanning electron microscope (SEM). It is also possible to similarly measure thicknesses of following layers forming graphite composite film 1.

It is possible to use graphite composite film 1 by, for example, peeling first peeling sheet 60 from graphite composite film 1 just before use and attaching graphite composite film 1 to an object to be adhered. Examples of the object to be adhered include an electronic component disposed within a housing of an electronic device. Examples of the electronic component include a rear chassis of a liquid crystal unit, a light-emitting diode (LED) substrate having a light-emitting diode (LED) light source used as, for example, a back light of a liquid crystal image display device, a power amplifier, and a large scale integrated circuit (LSI). As first peeling sheet 60, it is possible to use, for example, one obtained by performing, with, for example, a silicone resin, a peeling treatment on one or both surfaces of paper such as kraft paper, glassine paper, or pure paper; a resin film such as polyethylene, polypropylene (oriented polypropylene (OPP) or cast polypropylene (CPP)), or polyethylene terephthalate (PET); laminated paper obtained by stacking paper and a resin film; or paper filled with, for example, clay or polyvinyl alcohol.

In the present exemplary embodiment, graphite composite film 1 includes second electrically conductive adhesive layer 50L, graphite layer 40L, first electrically conductive adhesive layer 30L, metal layer 21, and protection film 10 stacked in this order. The present disclosure, however, is not limited to this structure, and graphite composite film 1 may have any structure as long as graphite layer 40L, first electrically conductive adhesive layer 30L, metal layer 21, and protection film 10 are disposed in this order. Further, a layer that does not inhibit the effects of the present disclosed technique may be stacked between these layers. As an example of this structure, a rust-proofing layer may be interposed between metal layer 21 and first electrically conductive adhesive layer 30L. As the rust-proofing layer, it is possible to use, for example, an organic coating film or a metal coating film Examples of the organic coating film include a benzotriazole coating film. As a raw material for the benzotriazole coating film, it is possible to use, for example, benzotriazole or a derivative of benzotriazole. As a raw material for the metal coating film, it is possible to use, for example, a pure metal such as zinc, nickel, chromium, titanium, aluminum, gold, silver, or palladium; or an alloy containing these pure metals.

In the present exemplary embodiment, end surface 40E of graphite layer 40L is covered with first electrically conductive adhesive layer 30L and second electrically conductive adhesive layer 50L. The present disclosed technique, however, is not limited to this configuration, and end surface 40E of graphite layer 40L may be exposed. In the present exemplary embodiment, an end surface of metal layer 21 is exposed as shown in FIG. 5B. The present disclosed technique, however, is not limited to this configuration, and the end surface of metal layer 21 may be covered with protection film 10. The end surface of metal layer 21 that is covered with protection film 10 is less likely to be corroded and thus makes the electromagnetic wave shielding performance of graphite composite film 1 further less likely to be degraded.

### (Protection Film 10)

Graphite composite film 1 includes protection film 10 as shown in FIG. 5A. This configuration is capable of suppressing progress of oxidation on first surface 21A on a protection film 10-disposed side of metal layer 21 and preventing a flaw on first surface 21A of metal layer 21. Further, it is possible to impart electrical insulating properties on surface 1B of graphite composite film 1.

As a raw material for protection film 10, it is possible to use, for example, polyester, polyethylene terephthalate, an olefin resin, a styrene resin, a vinyl chloride resin, polycarbonate, an acrylonitrile-styrene copolymer resin (AS resin), polyacrylonitrile, a butadiene resin, an acrylonitrile-butadiene-styrene copolymer resin (ABS resin), an acrylic resin, polyacetal, polyphenylene ether, a phenol resin, an epoxy resin, a melamine resin, a urea resin, a polyimide, a polysulfide, a polyurethane, a vinyl acetate resin, a fluorine resin, an aliphatic polyamide, a synthetic rubber, an aromatic polyamide, or polyvinyl alcohol. Protection film 10 may further contain a flame retardant, an antistatic agent, an antioxidant, a metal deactivator, a plasticizer, or a lubricant as necessary. Protection film 10 preferably has a thickness ranging from 0.5 μm to 200 μm, inclusive.

Protection film 10 has a solid form as a surface form when viewed in thickness direction T of graphite composite film 1. That is, protection film 10 is provided without a gap over a whole region of a surface of graphite composite film 1 and metal layer 21 is not exposed, when viewed in thickness direction T of graphite composite film 1.

### (Metal Layer 21)

Graphite composite film 1 includes metal layer 21 as shown in FIG. 5A. This configuration makes graphite composite film 1 have an electromagnetic wave shielding function.

Metal layer 21 is formed of a first metal. The first metal may be appropriately adjusted according to a raw material for graphite composite film 1, and it is possible to use, for example, silver, copper, gold, aluminum, magnesium, tungsten, cobalt, zinc, nickel, brass, potassium, lithium, iron, platinum, tin, chromium, lead, or titanium. Among these metals, the first metal is preferably a raw material having high electric conductivity in the raw material for graphite composite film 1 from a viewpoint of improving the electromagnetic wave shielding performance of graphite composite film 1. The first metal is more preferably copper from a viewpoint of, for example, having high electric conductivity and being relatively inexpensive.

The arithmetic average roughness (Ra) of second surface 21B of metal layer 21 is less than or equal to 50 nm, preferably less than or equal to 20 nm, more preferably less than or equal to 10 nm.

A maximum height roughness (Rz) of second surface 21B of metal layer 21 is preferably less than or equal to 200 nm, more preferably less than or equal to 100 nm. Here, the maximum height roughness (Rz) in the present application conforms to JISB0601: 2013. A method for measuring the maximum height roughness (Rz) is identical with a method for measuring the maximum height roughness (Rz) described in Example.

A ten-point average roughness (Rzjis) of second surface 21B of metal layer 21 is preferably less than or equal to 100 nm, more preferably less than or equal to 50 nm. Here, the ten-point average roughness (Rzjis) in the present application conforms to JISB0601: 2013. A method for measuring the ten-point average roughness (Rzjis) is identical with a method for measuring the ten-point average roughness (Rzjis) described in Example.

An arithmetic average roughness (Ra) of first surface 21A of metal layer 21 is preferably less than or equal to 20 nm, more preferably less than or equal to 10 nm. The arithmetic average roughness (Ra) of first surface 21A of metal layer 21 is measured by the identical method with the method for measuring the arithmetic average roughness (Ra) described in Example after removal of protection film 10. Examples of a method for removing protection film 10 include a method for dissolving protection film 10 with hexafluoroisopropanol.

A maximum height roughness (Rz) of first surface 21A of metal layer 21 is preferably less than or equal to 200 nm, more preferably less than or equal to 100 nm. The maximum height roughness (Rz) of first surface 21A of metal layer 21 is measured by the identical method with the method for measuring the maximum height roughness (Rz) described in Example after removal of protection film 10.

A ten-point average roughness (Rzjis) of first surface 21A of metal layer 21 is preferably less than or equal to 100 nm, more preferably less than or equal to 50 nm. The ten-point average roughness (Rzjis) of first surface 21A of metal layer 21 is measured by the identical method with the method for measuring the ten-point average roughness (Rzjis) described in Example after removal of protection film 10.

Metal layer 21 has a thickness ranging preferably from 0.10 μm to 5.00 μm, inclusive, more preferably from 0.50 μm to 2.00 μm, inclusive. Metal layer 21 having a thickness in the above range gives graphite composite film 1 that is light and has excellent flexibility. This configuration enables easy attachment of graphite composite film 1 even to an object to be adhered having a non-flat adhesion surface, to be capable of broadening freedom of disposition of graphite composite film 1.

In the present exemplary embodiment, the arithmetic average roughness (Ra) of second surface 21B of metal layer 21 is less than or equal to 50 nm. The present disclosed technique, however, is not limited to this configuration, and metal layer 21 is acceptable as long as at least one of first surface 21A or second surface 21B of metal layer 21 has an arithmetic average roughness (Ra) of less than or equal to 50 nm. As an example of this configuration, only first surface 21A of metal layer 21 has an arithmetic average roughness (Ra) of less than or equal to 50 nm or first surface 21A and second surface 21B of metal layer 21 may have an arithmetic average roughness (Ra) of less than or equal to 50 nm. The eddy current is supposed to be induced on a surface having a smaller arithmetic average roughness (Ra), that is, on a surface having less eddy current loss.

In the present exemplary embodiment, metal layer 21 has a solid form as a surface form when viewed in thickness direction T of metal layer 21. The present disclosed technique, however, is not limited to this form. Exemplary alternatives of the surface form include a mesh form and a wire form. Metal layer 21 has thickness T21 ranging preferably from 0.10 μm to 5.00 μm, inclusive, more preferably from 0.50 μm to 2.00 μm, inclusive. Second metal layer 80 has thickness T80 ranging preferably from 0.002 μm to 0.100 μm, inclusive, more preferably from 0.002 μm to 0.040 μm, inclusive.

### (First Electrically Conductive Adhesive Layer 30L)

Graphite composite film 1 includes first electrically conductive adhesive layer 30L as shown in FIG. 5A. This configuration enables metal layer 21 to be both adhesively fixed and electrically connected to graphite layer 40L.

First electrically conductive adhesive layer 30L includes, as shown in FIG. 5A, first adhesion layer 31, first metal substrate 32, and second adhesion layer 33 stacked in this order. First electrically conductive adhesive layer 30L that includes first metal substrate 32 has excellent electric conductivity. First electrically conductive adhesive layer 30L preferably has a thickness ranging from 2 μm to 300 μm, inclusive. First electrically conductive adhesive layer 30L has a solid form as a surface form when viewed in thickness direction T of graphite composite film 1.

First adhesion layer 31 is formed of an electrically conductive adhesive agent having electric conductivity and adhesion. The electrically conductive adhesive agent contains, for example, a polymer and an electrically conductive filler and may further contain a crosslinking agent, an additive, or a solvent as necessary. As the polymer, it is possible to use, for example, an acrylic polymer, a rubber polymer, a silicone polymer, or a urethane polymer. Among these polymers, an acrylic polymer and a rubber polymer are preferably used from a viewpoint of being less likely to cause peeling by an influence of heat even when graphite composite film 1 is attached to a heat generating member. As the acrylic polymer, it is possible to use one obtained by polymerizing a vinyl monomer such as a (meth)acrylic monomer. As the electrically conductive filler, it is possible to use, for example, a metal filler, a carbon filler, a metal composite filler, a metal oxide filler, or a potassium titanate filler. Examples of a raw material for the metal filler include silver, nickel, copper, tin, aluminum, and stainless steel. As a raw material for the carbon filler, it is possible to use, for example, Ketjen black, acetylene black, or graphite. As a raw material for the metal composite filler, it is possible to use, for example, aluminum-coated glass, nickel-coated glass, silver-coated glass, or nickel-coated carbon. As a raw material for the metal oxide filler, it is possible to use, for example, antimony-doped tin oxide, tin-doped indium oxide, or aluminum-doped zinc oxide. A shape of the electrically conductive filler is not particularly limited, and examples of the shape include powder, flakes, and fibers. As the crosslinking agent, it is possible to use, for example, an isocyanate crosslinking agent, an epoxy crosslinking agent, a chelate crosslinking agent, or an aziridine crosslinking agent. As the additive, it is possible to use a tackifying resin for a purpose of further improving adhesive power of first adhesion layer 31. As the tackifying resin, it is possible to use, for example, a rosin resin; a terpene resin; an aliphatic (C5) or aromatic (C9) petroleum resin; a styrene resin; a phenolic resin; a xylene resin; or a methacrylic resin. First adhesion layer 31 has a thickness ranging preferably from 0.2 μm to 50 μm, inclusive, more preferably from 2 μm to 20 μm, inclusive.

As a raw material for first metal substrate 32, it is possible to use, for example, gold, silver, copper, aluminum, nickel, iron, tin, or an alloy of these metals. Among these metals, the raw material for first metal substrate 32 is preferably aluminum or copper from viewpoints of, for example, flexibility and thermal and electric conductivity, and is further preferably aluminum from a viewpoint of, for example, being less likely to promote corrosion by metal passivation. As the metal substrate formed of aluminum, it is possible to use a hard aluminum substrate formed of hard aluminum or a soft aluminum substrate formed of soft aluminum. The hard aluminum substrate is formed of aluminum foil obtained by subjecting aluminum to rolling. The soft aluminum substrate is formed of aluminum foil obtained by subjecting aluminum to rolling and annealing. As the metal substrate formed of copper, it is possible to use, for example, a substrate formed of electrolytic copper or a substrate formed of rolled copper. First metal substrate 32 has a thickness of preferably less than or equal to 200 μm, more preferably less than or equal to 100 μm.

Second adhesion layer 33 has electric conductivity and adhesion and contains, for example, a polymer and an electrically conductive filler. Second adhesion layer 33 has the same composition as first adhesion layer 31.

In the present exemplary embodiment, first electrically conductive adhesive layer 30L includes, as shown in FIG. 5A, first adhesion layer 31, first metal substrate 32, and second adhesion layer 33 stacked in this order. The present disclosed technique, however, is not limited to this structure. As an exemplary alternative, first electrically conductive adhesive layer 30L may be a single layer formed of an electrically conductive resin. In the present exemplary embodiment, second adhesion layer 33 has the same composition as first adhesion layer 31. The present disclosed technique, however, is not limited to this configuration, and second adhesion layer 33 may have a different composition from the composition of first adhesion layer 31 as long as second adhesion layer 33 has electric conductivity and adhesion.

### (Graphite Layer 40L)

Graphite composite film 1 includes graphite layer 40L as shown in FIG. 5A. This configuration enables graphite composite film 1 to both efficiently conduct and dissipate heat of an object to be adhered and improve the electromagnetic wave shielding performance.

Graphite layer 40L has excellent electric conductivity and thermal conductivity in the plane direction. As a raw material for graphite layer 40L, it is possible to use, for example, a layered carbon crystal graphite or a graphite intercalation compound formed through penetration of a chemical species between layers of graphite as a matrix. Examples of the chemical species include potassium, lithium, bromine, nitric acid, iron(III) chloride, tungsten hexachloride, and arsenic pentafluoride. Graphite layer 40L may be, for example, one obtained by stacking one or a plurality of graphite films. As the graphite film, it is possible to use, for example, a pyrolytic graphite sheet produced by firing a polymer film at high temperature or an expanded graphite sheet produced by an expanded graphite method. Among these graphite sheets, it is preferable to use, as the graphite film, a pyrolytic graphite sheet produced by firing a polymer film at high temperature, from a viewpoint of having high thermal conductivity, being light and flexible, and facilitating processing. As the polymer film, it is possible to use, for example, a heat-resistance aromatic polymer such as a polyimide, a polyamide, or a polyamide-imide. A temperature for firing the polymer film preferably ranges from 2600° C. to 3000° C., inclusive. The expanded graphite method is a method for forming an intercalation compound through treatment of natural graphite with a strong acid such as sulfuric acid, heating and expanding the intercalation compound to produce expanded graphite, and subjecting the expanded graphite to rolling to form the expanded graphite into a sheet. The graphite film preferably has a thickness ranging from 10 μm to 100 μm, inclusive.

The pyrolytic graphite sheet preferably has an a-b plane-direction coefficient of thermal conductivity ranging from 700 W/(m·k) to 1950 W/(m·k), inclusive and preferably has a c-axis-direction coefficient of thermal conductivity ranging from 8 W/(m·K) to 15 W/(m·k), inclusive. The pyrolytic graphite sheet preferably has a density ranging from 0.85 g/cm³ to 2.13 g/cm³, inclusive. As such a pyrolytic graphite sheet, it is possible to use, for example, a “PGS (registered trademark) graphite sheet” manufactured by Panasonic Corporation.

Graphite layer 40L has a thickness ranging preferably from 5 μm to 500 μm, inclusive, more preferably from 10 μm to 200 μm, inclusive. Graphite layer 40L has a solid form as a surface form when viewed in thickness direction T of graphite composite film 1.

### (Second Electrically Conductive Adhesive Layer 50L)

Graphite composite film 1 includes second electrically conductive adhesive layer 50L as shown in FIG. 5A. This configuration enables graphite composite film 1 to be adherent to an object to be adhered, allowing graphite composite film 1 to both easily exhibit excellent heat dissipation properties and electrically connect graphite layer 40L to the object to be adhered. Thus, metal layer 21 is electrically connected to the object to be adhered, so that when the object to be adhered has electric conductivity, graphite composite film 1 has more excellent electromagnetic wave shielding performance.

Second electrically conductive adhesive layer 50L includes, as shown in FIG. 5A, third adhesion layer 51, second metal substrate 52, and fourth adhesion layer 53 stacked in this order. Second electrically conductive adhesive layer 50L has the same structure as first electrically conductive adhesive layer 30L.

In the present exemplary embodiment, second electrically conductive adhesive layer 50L includes, as shown in FIG. 5A, third adhesion layer 51, second metal substrate 52, and fourth adhesion layer 53 stacked in this order. The present disclosed technique, however, is not limited to this structure. As an exemplary alternative, second electrically conductive adhesive layer 50L may be a single layer formed of an electrically conductive resin. In the present exemplary embodiment, second electrically conductive adhesive layer 50L has the same structure as first electrically conductive adhesive layer 30L. The present disclosed technique, however, is not limited to this configuration, and second electrically conductive adhesive layer 50L may have a different structure from the structure of first electrically conductive adhesive layer 30L as long as second electrically conductive adhesive layer 50L has electric conductivity and adhesion.

### [Method for Producing Graphite Composite Film According to Present Exemplary Embodiment]

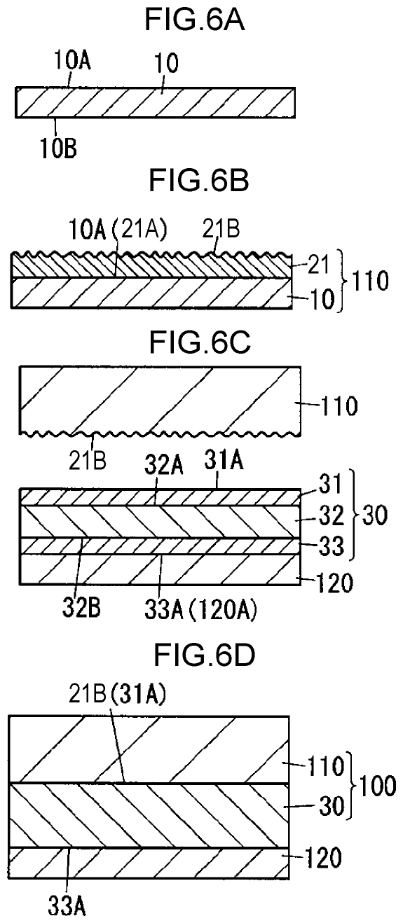

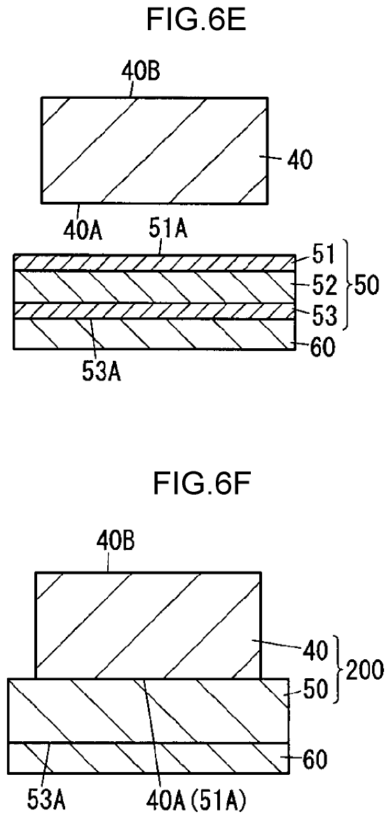

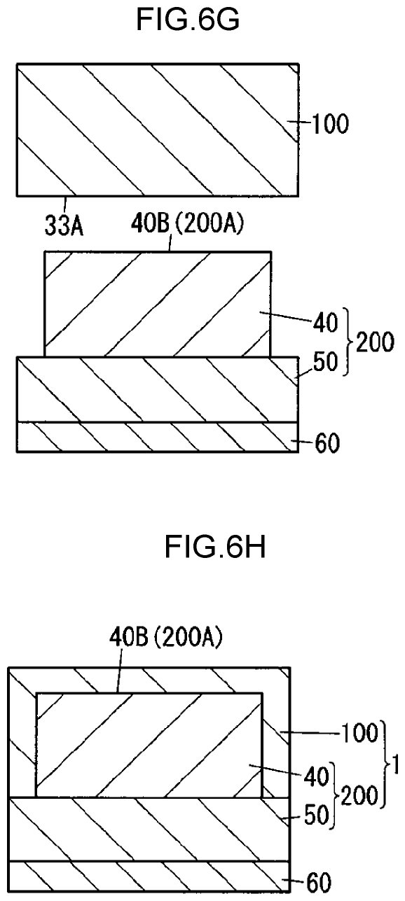

FIGS. 6A to 6H are schematic sectional views for illustrating a method for producing graphite composite film 1 according to the present exemplary embodiment. Specifically, FIGS. 6A to 6D are schematic sectional views for illustrating step (A) of preparing electrically conductive adhesive sheet-attached metal vapor-deposited film 100. FIGS. 6E and 6F are schematic sectional views for illustrating step (B) of preparing electrically conductive adhesive sheet-attached graphite film 200. FIGS. 6G and 6H are schematic sectional views for illustrating step (C) of subjecting electrically conductive adhesive sheet-attached metal vapor-deposited film 100 and electrically conductive adhesive sheet-attached graphite film 200 to lamination. Constituent members in FIGS. 6A to 6H that are identical with the constituent members of the exemplary embodiment shown in FIG. 5A are denoted by identical reference marks and are not sometimes described redundantly. Graphite film 40 corresponds to graphite layer 40L, first electrically conductive adhesive sheet 30 corresponds to first electrically conductive adhesive layer 30L, and second electrically conductive adhesive sheet 50 corresponds to second electrically conductive adhesive layer 50L.

The method for producing graphite composite film 1 according to the present exemplary embodiment includes step (A) of preparing electrically conductive adhesive sheet-attached metal vapor-deposited film 100, step (B) of preparing electrically conductive adhesive sheet-attached graphite film 200, and step (C) of subjecting electrically conductive adhesive sheet-attached metal vapor-deposited film 100 and electrically conductive adhesive sheet-attached graphite film 200 to lamination. Steps (A), (B), and (C) are performed in this order. These steps give graphite composite film 1 that is capable of attaining both a measure against heat and a measure against electromagnetic noise and that has excellent high-frequency electromagnetic wave shielding performance.

Step (A): vapor deposition of a first metal is performed on first surface 10A of protection film 10 having first surface 10A and second surface 10B, to form metal layer 21 having first surface 21A and second surface 21B and thus prepare metal vapor-deposited film 110 (hereinafter, step (a1)), and first electrically conductive adhesive sheet 30 is disposed on second surface 21B of metal layer 21 in metal vapor-deposited film 110, thus laminating second surface 21B with first electrically conductive adhesive sheet 30 (hereinafter, step (a2)).

Step (B): second electrically conductive adhesive sheet 50 is disposed on first surface 40A of graphite film 40 having first surface 40A and second surface 40B, thus laminating first surface 40A with second electrically conductive adhesive sheet 50.

Step (C): electrically conductive adhesive sheet-attached metal vapor-deposited film 100 and electrically conductive adhesive sheet-attached graphite film 200 are subjected to lamination, with surface 33A of first electrically conductive adhesive sheet 30 and second surface 40B of graphite film 40 disposed so as to overlap one another.

In the present exemplary embodiment, steps (A), (B), and (C) are performed in this order. The present disclosed technique, however, is not limited to this order. As an exemplary alternative, the steps may be performed in an order of steps (B), (A), and (C).

### [Step (A)]

Step (A) includes step (a1) of preparing metal vapor-deposited film 110 and step (a2) of subjecting metal vapor-deposited film 110 and first electrically conductive adhesive sheet 30 to lamination, that are performed in this order. These procedures prepare electrically conductive adhesive sheet-attached metal vapor-deposited film 100 shown in FIG. 6D.

(Step (a1))

In step (a1), vapor deposition of a first metal is performed on first surface 10A of protection film 10 shown in FIG. 6A to form metal layer 21 shown in FIG. 6B. Step (a1) gives metal vapor-deposited film 110 shown in FIG. 6B.

A method for performing the vapor deposition of the first metal is preferably a vacuum vapor deposition method. As a method for setting the arithmetic average roughness (Ra) of second surface 21B of metal layer 21 at less than or equal to 50 nm, a method is exemplified that includes appropriately adjusting, for example, a degree of vacuum and a temperature in a vacuum furnace. When metal layer 21 is formed by a vacuum vapor deposition method, a surface state of first surface 21A of metal layer 21 does not completely conform to a surface state of first surface 10A of protection film 10, and the arithmetic average roughness (Ra) of first surface 21A of metal layer 21 tends to be smaller than an arithmetic average roughness (Ra) of first surface 10A of protection film 10. Adjusting the degree of vacuum enables formation of metal layer 21 that has first surface 21A and second surface 21B having different arithmetic average roughness (Ra). Formation of such metal layer 21 is exemplified as follows: when a vaporized or sublimated first metal is attached to or deposited on first surface 10A of elongated protection film 10 under conveyance of protection film 10 in a vacuum case to form metal layer 21, partially adjusting the degree of vacuum so as to make the degree of vacuum higher in a deposition initial stage than in a deposition terminal stage enables formation of metal layer 21 having first surface 21A that has a smaller arithmetic average roughness(Ra) than the arithmetic average roughness (Ra) of second surface 21B.

Step (a1) may continuously form metal layer 21 by, for example, performing vapor deposition of the first metal on first surface 21A of elongated protection film 10.

(Step (a2))

In step (a2), first electrically conductive adhesive sheet 30 is, as shown in FIG. 6C, disposed on second surface 21B of metal layer 21 in metal vapor-deposited film 110, thus laminating second surface 21B with first electrically conductive adhesive sheet 30. At this time, second peeling sheet 120 is, as shown in FIG. 6C, fitted to surface 33A of first electrically conductive adhesive sheet 30 from a viewpoint of easy handling. Step (a2) gives electrically conductive adhesive sheet-attached metal vapor-deposited film 100 shown in FIG. 6D.

Examples of a method for producing second peeling sheet 120-fitted first electrically conductive adhesive sheet 30 shown in FIG. 6C include a method including following steps. The method includes, for example, a step of applying an electrically conductive adhesive agent onto a surface of a third peeling sheet to form first adhesion layer 31. The method includes a step of applying an electrically conductive adhesive agent onto surface 120A of second peeling sheet 120 and drying the electrically conductive adhesive agent to form second adhesion layer 33. Then, the method includes a step of attaching first adhesion layer 31 and second adhesion layer 33 respectively to first surface 32A and second surface 32B of first metal substrate 32 having first surface 32A and second surface 32B, to form a laminated film, and curing the laminated film and then peeling the third peeling sheet from the laminated film. Examples of a method for applying the electrically conductive adhesive agent include a method with use of, for example, a roll coater or a die coater. When the electrically conductive adhesive agent contains a solvent, the drying is preferably performed in an environment with a temperature approximately ranging from 50° C. to 120° C. to remove the solvent. As a treatment condition for the curing, a treatment temperature preferably ranges from 15° C. to 50° C., inclusive, and a treatment period preferably ranges from 48 hours to 168 hours, inclusive. Second peeling sheet 120 and the third peeling sheet have the same structure as first peeling sheet 60.

Examples of a method for subjecting metal vapor-deposited film 110 and first electrically conductive adhesive sheet 30 to lamination include a method for disposing metal vapor-deposited film 110 and first electrically conductive adhesive sheet 30 such that second surface 20B of metal vapor-deposited film 110 faces surface 31A of first electrically conductive adhesive sheet 30, and making second surface 20B of metal vapor-deposited film 110 adherent to surface 31A of first electrically conductive adhesive sheet 30 by pressure contact.

Step (a2) may continuously produce electrically conductive adhesive sheet-attached metal vapor-deposited film 100 by, for example, sending elongated metal vapor-deposited film 110 and elongated first electrically conductive adhesive sheet 30 out to between a pair of rolls and sandwiching metal vapor-deposited film 110 and first electrically conductive adhesive sheet 30 between the pair of rolls for surface contact to perform lamination.

In the present exemplary embodiment, second peeling sheet 120 is fitted to surface 33A of first electrically conductive adhesive sheet 30. The present disclosed technique, however, is not limited to this configuration, and second peeling sheet 120 need not be fitted to surface 33A of first electrically conductive adhesive sheet 30.

### [Step (B)]

In step (B), second electrically conductive adhesive sheet 50 is, as shown in FIG. 6E, disposed on first surface 40A of graphite film 40 having first surface 40A and second surface 40B, thus laminating first surface 40A with second electrically conductive adhesive sheet 50. At this time, first peeling sheet 60 is, as shown in FIG. 6E, fitted to surface 53A of second electrically conductive adhesive sheet 50 from a viewpoint of easy handling. Step (B) gives electrically conductive adhesive sheet-attached graphite film 200 shown in FIG. 6F.

Examples of a method for producing first peeling sheet 60-fitted second electrically conductive adhesive sheet 50 shown in FIG. 6E include the same method as the above-mentioned method for producing second peeling sheet 120-fitted first electrically conductive adhesive sheet 30 shown in FIG. 6C.

Examples of a method for subjecting graphite film 40 and second electrically conductive adhesive sheet 50 to lamination include a method for disposing second electrically conductive adhesive sheet 50 as shown in FIG. 6E such that surface 51A of second electrically conductive adhesive sheet 50 is directed upward and placing graphite film 40 that has been cut into a prescribed dimension on surface 51A of second electrically conductive adhesive sheet 50. The dimension of cut graphite film 40 may be any dimension as long as entire graphite film 40 is, as shown in FIG. 6H, covered with electrically conductive adhesive sheet-attached metal vapor-deposited film 100 and electrically conductive adhesive sheet-attached graphite film 200. Covering entire graphite film 40 with electrically conductive adhesive sheet-attached metal vapor-deposited film 100 and electrically conductive adhesive sheet-attached graphite film 200 is capable of preventing rupture of graphite composite film 1 attributed to interlayer peeling in graphite layer 40L and preventing powder dropping of graphite layer 40L.

Step (B) may continuously produce electrically conductive adhesive sheet-attached graphite film 200 by, for example, continuously sending second electrically conductive adhesive sheet 50 out to a laminate producing step and continuously placing, with a prescribed interval, cut graphite film 40 on surface 51A of second electrically conductive adhesive sheet 50.

In the present exemplary embodiment, cut graphite film 40 is placed on surface 51A of second electrically conductive adhesive sheet 50, thus laminating graphite film 40 with second electrically conductive adhesive sheet 50. The present disclosed technique, however, is not limited to this lamination process. For example, the lamination may be performed by continuously sending each of elongated graphite film 40 and elongated second electrically conductive adhesive sheet 50 out to between a pair of rolls and sandwiching graphite film 40 and second electrically conductive adhesive sheet 50 between the pair of rolls for surface contact.

### [Step (C)]

In step (C), electrically conductive adhesive sheet-attached metal vapor-deposited film 100 and electrically conductive adhesive sheet-attached graphite film 200 are, as shown in FIG. 6G, subjected to lamination, with surface 33A of first electrically conductive adhesive sheet 30 and second surface 40B of graphite film 40 disposed so as to overlap one another. At this time, second peeling sheet 120 has been peeled as shown in FIG. 6G. First peeling sheet 60 is kept fitted from a viewpoint of easy handling of graphite composite film 1. Step (C) gives graphite composite film 1 shown in FIG. 6H.

Examples of a method for subjecting electrically conductive adhesive sheet-attached metal vapor-deposited film 100 and electrically conductive adhesive sheet-attached graphite film 200 to lamination include a following method. A method is exemplified that includes disposing electrically conductive adhesive sheet-attached graphite film 200 as shown in FIG. 6G such that surface 200A on a graphite film 40-disposed side is directed upward and placing electrically conductive adhesive sheet-attached metal vapor-deposited film 100 on surface 200A of electrically conductive adhesive sheet-attached graphite film 200 so as to cover entire graphite film 40.

In step (C), for example, elongated electrically conductive adhesive sheet-attached metal vapor-deposited film 100 and elongated electrically conductive adhesive sheet-attached graphite film 200 are sent out to between a pair of rolls. Then, electrically conductive adhesive sheet-attached metal vapor-deposited film 100 and electrically conductive adhesive sheet-attached graphite film 200 may be sandwiched between the pair of rolls for surface contact to perform lamination, followed by cutting into a necessary size, to continuously produce graphite composite film 1.

The present exemplary embodiment includes steps (A), (B), and (C). The present disclosed technique, however, is not limited to this stacking order, and following methods are exemplified. A method is exemplified that includes subjecting metal vapor-deposited film 110, first electrically conductive adhesive sheet 30, graphite film 40, and second electrically conductive adhesive sheet 50 simultaneously to lamination to produce graphite composite film 1. Another method is exemplified that includes subjecting first electrically conductive adhesive sheet 30, graphite film 40, and second electrically conductive adhesive sheet 50 to lamination to give a laminated film and subjecting the obtained laminated film and metal vapor-deposited film 110 to lamination to produce graphite composite film 1. Another method is also exemplified that includes subjecting metal vapor-deposited film 110, first electrically conductive adhesive sheet 30, and graphite film 40 to lamination to give a laminated film and subjecting the obtained laminated film and second electrically conductive adhesive sheet 50 to lamination to produce graphite composite film 1.

### Example

Hereinafter, the present exemplary embodiment is specifically described by way of an example.

### [Measurement of Surface States]

A scanning probe microscope (“SPM-9600” manufactured by SHIMADZU CORPORATION) was used for measuring the arithmetic average roughness (Ra), the maximum height roughness (Rz), and the ten-point average roughness (Rzjis) of a metal layer. Specifically, a metal vapor-deposited film or a metal film was fixed to a metal plate, three surface measurement locations A, B, and C were selected, with a measuring range set at 1 μm×1 μm or 10 μm×10 μm, and each of the locations was measured for the arithmetic average roughness (Ra), the maximum height roughness (Rz), and the ten-point average roughness (Rzjis) by surface analysis software built in the scanning probe microscope. An average value of measured values at these three locations was defined as the arithmetic average roughness (Ra), the maximum height roughness (Rz), or the ten-point average roughness (Rzjis).

### Example 2

### [Step (A)]

(Step (a1))

As protection film 10, a polyester film (“CX40” manufactured by Toray Industries, Inc., main raw material: PET, thickness: 6 μm) was prepared. This polyester film was disposed in a vacuum case and a first metal was attached to or deposited on first surface 10A of protection film 10 with use of copper (oxygen-free copper manufactured by Hitachi Metals Neomaterial, Ltd.) as the first metal while the degree of vacuum and the temperature in vacuum vapor deposition were adjusted, to form metal layer 21 (thickness: 1 μm). These procedures gave metal vapor-deposited film 110 shown in FIG. 6B. Second surface 21B of metal layer 21 in obtained metal vapor-deposited film 110 was measured for the surface states. Table 4 shows results of the measurement.

(Step (a2))

As second peeling sheet 120-fitted first electrically conductive adhesive sheet 30, a sheet was prepared that was obtained by peeling a peeling sheet from one surface 31A of an electrically conductive double coated adhesive sheet (DAITAC (registered trademark) “#8506ADW-10-H2” manufactured by DIC Corporation, metal substrate: substrate formed of aluminum, thickness: 10 μm).

As shown in FIG. 6C, metal vapor-deposited film 110 and first electrically conductive adhesive sheet 30 were disposed such that second surface 20B of metal vapor-deposited film 110 faces surface 31A of first electrically conductive adhesive sheet 30, and second surface 21B of metal vapor-deposited film 110 was made adherent to surface 31A of first electrically conductive adhesive sheet 30 by pressure contact. These procedures gave electrically conductive adhesive sheet-attached metal vapor-deposited film 100 shown in FIG. 6D.

### [Step (B)]

As first peeling sheet 60-fitted second electrically conductive adhesive sheet 50, a sheet was prepared that was obtained by peeling a peeling sheet from one surface 51A from an electrically conductive double coated adhesive sheet, i.e., the same product as first electrically conductive adhesive sheet 30. As graphite film 40, a graphite film (“PGS (registered trademark) graphite sheet” manufactured by Panasonic Corporation, thickness: 25 μm) cut into a size of 10 cm×12 cm was prepared.

As shown in FIG. 6E, second electrically conductive adhesive sheet 50 was disposed such that surface 51A of second electrically conductive adhesive sheet 50 was directed upward, and graphite film 40 was placed on surface 51A of second electrically conductive adhesive sheet 50. These procedures gave electrically conductive adhesive sheet-attached graphite film 200 shown in FIG. 6F.

### [Step (C)]

As shown in FIG. 6G, electrically conductive adhesive sheet-attached graphite film 200 was disposed such that surface 200A on a graphite film 40-disposed side was directed upward, and electrically conductive adhesive sheet-attached metal vapor-deposited film 100 was placed on surface 200A of electrically conductive adhesive sheet-attached graphite film 200 so as to cover entire graphite film 40 and was cut into a size of 10 cm×12 cm. These procedures gave graphite composite film 1 shown in FIG. 6H.

### Comparative Example 2

As protection film 10, a polyester film (“CX40” manufactured by Toray Industries, Inc., main raw material: PET, thickness: 6 μm) was prepared. An electrolytic copper foil (“F2-WS” manufactured by Furukawa Electric Co., Ltd.) was prepared as a sheet for forming metal layer 21 (hereinafter, a metal layer forming sheet). An adhesive agent (“CT-4040” manufactured by DIC Corporation) was applied to first surface 10A of protection film 10 to form an adhesive layer, a surface of this adhesive layer was made adherent to a surface on an electrolytic copper foil-disposed side of the metal layer forming sheet by pressure contact to give a stacked product, and a metal film was obtained from the obtained stacked product. The adhesive layer had a thickness of 20 μm. A surface of a metal layer in the obtained metal film was measured for the surface states. Table 5 shows results of the measurement.

Graphite composite film 1 was obtained in the same manner as Example 2 except that the metal film was used in place of metal vapor-deposited film 110.

### [Measurement Test for Electromagnetic Wave Shielding Performance]

Samples obtained by peeling first peeling sheet 60 from obtained graphite composite films 1 were measured for the electromagnetic field shielding performance at a frequency range of 8 GHz in accordance with a coaxial line method.

Table 6 shows results of the measurement for the electromagnetic field shielding performance of the samples.

TABLE 4

| | Example 2 | | | | | | | |
|---|---|---|---|---|---|---|---|---|
| | Measurement | Measurement | Measurement | Average | Measurement | Measurement | Measurement | Average |
| | location A | location B | location C | value | location A | location B | location C | value |
| | Measuring range | | | | | | | |
| | 10 μm × 10 μm | | | | 1 μm × 1 μm | | | |
| Ra (nm) | 10.8 | 15.4 | 14.0 | 13.4 | 7.6 | 7.9 | 8.4 | 8.0 |
| Rz (nm) | 170 | 225 | 176 | 190 | 96 | 84 | 81 | 87 |
| Rzjis (nm) | 82 | 103 | 87 | 91 | 48 | 41 | 40 | 43 |

TABLE 5

| | Comparative Example 2 | | | | | | | |
|---|---|---|---|---|---|---|---|---|
| | Measuement | Measurement | Measurement | Average | Measurement | Measurement | Measurement | Average |
| | location A | location B | location C | value | location A | location B | location C | value |
| | Measuring range | | | | | | | |
| | 10 μm × 10 μm | | | | 1 μm × 1 μm | | | |
| Ra (nm) | 73.9 | 58.6 | 82.1 | 71.5 | 62.5 | 59.8 | 76.0 | 66.1 |
| Rz (nm) | 699 | 519 | 761 | 660 | 352 | 269 | 420 | 347 |
| Rzjis (nm) | 344 | 248 | 369 | 320 | 192 | 152 | 223 | 189 |

TABLE 6

| | Arithmetic | Electromagnetic |
|---|---|---|
| | average roughness | field shielding |
| | (Ra) of second surface | performance at 8 GHz |
| | (nm) | (dB) |
| Example 2 | 8.0 | 100 |
| Comparative | 66.1 | 90 |
| Example 2 | | |

The graphite composite film and the method for producing the graphite composite film according to the present disclosure are capable of giving a graphite composite film that is capable of attaining both a measure against heat and a measure against electromagnetic noise and that has excellent high-frequency electromagnetic wave shielding performance. Thus, the graphite composite film and the method for producing the graphite composite film according to the present disclosure are industrially useful.

What is claimed is:

1. A graphite composite film comprising a graphite layer, a first electrically conductive adhesive layer, a first metal layer containing a first metal, and a second metal layer containing a second metal disposed in this order,
wherein at least one of Ra₁ or Ra₂ is less than or equal to 50 nm,
where Ra₁ is an arithmetic average roughness of a surface of the first metal layer, the surface being a surface on which the first electrically conductive adhesive layer is disposed, and
Ra₂ is an arithmetic average roughness of a first surface of the second metal layer, the first surface opposing a second surface of the second metal layer, the second surface being a surface on which the first metal layer is disposed.

2. The graphite composite film according to claim 1,
wherein the first metal is copper.

3. The graphite composite film according to claim 1,
wherein the second metal is at least one of zinc, nickel, chromium, titanium, aluminum, gold, silver, palladium, and an alloy, the alloy including one of zinc, nickel, chromium, titanium, aluminum, gold, silver, and palladium.

4. The graphite composite film according to claim 1,
wherein the second metal layer has a thickness of less than or equal to a thickness of the first metal layer.

5. The graphite composite film according to claim 4,
wherein the first metal layer has a thickness ranging from 0.10 μm to 5.00 μm, inclusive.

6. The graphite composite film according to claim 4,
wherein the second metal layer has a thickness ranging from 0.002 μm to 0.100 μm, inclusive.

7. A method for producing a graphite composite film, the method comprising the steps of;
forming a metal vapor-deposited film attached with a first electrically conductive adhesive sheet, by (i) performing vapor deposition of a first metal on a surface of a protection film to form a first metal layer, (ii) disposing the first electrically conductive adhesive sheet on a first surface of the first metal layer, and (iii) peeling the protection film from the first metal layer, and (iv) performing vapor deposition of a second metal on a second surface of the first metal layer opposite from the first surface to form a second metal layer;
forming a graphite film attached with a second electrically conductive adhesive sheet, by disposing the second electrically conductive adhesive sheet on a first surface of a graphite film having the first surface and a second surface opposing each other; and
laminating the metal vapor-deposited film attached with the first electrically conductive adhesive sheet onto the graphite film attached with the second electrically conductive adhesive sheet, by disposing a surface of the first electrically conductive adhesive sheet on the second surface of the graphite film,
with an arithmetic average roughness of the surface on the first electrically conductive adhesive sheet-disposed side of the first metal layer defined as Ra₁ and an arithmetic average roughness of a surface of the second metal layer opposite from a surface on a first metal layer-disposed side of the second metal layer defined as Ra₂, at least one of the Ra₁ or the Ra₂ being less than or equal to 50 nm.

8. The method for producing a graphite composite film according to claim 7,
wherein the first metal is copper.

9. The method for producing a graphite composite film according to claim 7,
wherein the second metal is at least one metal selected from the group consisting of zinc, nickel, chromium, titanium, aluminum, gold, silver, palladium, and an alloy of these metals.

10. A method for producing a graphite composite film, the method comprising the steps of;
performing vapor deposition of a second metal and a first metal in this order on a first surface of a protection film having the first surface and a second surface, to form a second metal layer containing the second metal and a first metal layer containing the first metal, disposing a first electrically conductive adhesive sheet on a surface of the first metal layer, thus laminating the surface with the first electrically conductive adhesive sheet, and peeling the protection film to prepare a first electrically conductive adhesive sheet-attached metal vapor-deposited film;
disposing a second electrically conductive adhesive sheet on a first surface of a graphite film having the first surface and a second surface, thus laminating the first surface with the second electrically conductive adhesive sheet, to prepare a second electrically conductive adhesive sheet-attached graphite film; and
subjecting the first electrically conductive adhesive sheet-attached metal vapor-deposited film and the second electrically conductive adhesive sheet-attached graphite film to lamination, with a surface of the first electrically conductive adhesive sheet and the second surface of the graphite film disposed so as to overlap one another,
with an arithmetic average roughness of a surface on a first electrically conductive adhesive sheet-disposed side of the first metal layer defined as Ra₁ and an arithmetic average roughness of a surface of the second metal layer opposite from a surface on a first metal layer-disposed side of the second metal layer defined as Ra₂, at least one of the Ra₁ or the Ra₂ being less than or equal to 50 nm.

11. The method for producing a graphite composite film according to claim 10,
wherein the first metal is copper.

12. The method for producing a graphite composite film according to claim 10,
wherein the second metal is at least one metal selected from the group consisting of zinc, nickel, chromium, titanium, aluminum, gold, silver, palladium, and an alloy of these metals.

13. A graphite composite film comprising a graphite layer, a first electrically conductive adhesive layer, a metal layer that contains a metal and has a first surface and a second surface, and a protection film in this order, with the protection film disposed to position on a side of the first surface of the metal layer,
at least one of the first surface or the second surface of the metal layer having an arithmetic average roughness of less than or equal to 50 nm.

14. The graphite composite film according to claim 13,
wherein the metal is copper.

15. The graphite composite film according to claim 13,
wherein the metal layer has a thickness ranging from 0.10 μm to 5.00 μm, inclusive.

16. The graphite composite film according to claim 13, further comprising a second electrically conductive adhesive layer on a surface of the graphite layer opposite from a surface on a first electrically conductive adhesive layer-disposed side of the graphite layer.

17. A method for producing a graphite composite film, the method comprising the steps of;
performing vapor deposition of a metal on a first surface of a protection film having the first surface and a second surface, to form a metal layer having a first surface and a second surface, and disposing a first electrically conductive adhesive sheet on the second surface of the metal layer, thus laminating the second surface with the first electrically conductive adhesive sheet, to prepare a first electrically conductive adhesive sheet-attached metal vapor-deposited film;
disposing a second electrically conductive adhesive sheet on a first surface of a graphite film having the first surface and a second surface, thus laminating the first surface with the second electrically conductive adhesive sheet, to prepare a second electrically conductive adhesive sheet-attached graphite film; and
subjecting the first electrically conductive adhesive sheet-attached metal vapor-deposited film and the second electrically conductive adhesive sheet-attached graphite film to lamination, with a surface of the first electrically conductive adhesive sheet and the second surface of the graphite film disposed so as to overlap one another,
at least one of the first surface or the second surface of the metal layer having an arithmetic average roughness Ra of less than or equal to 50 nm.
